(19) United States
(12) Patent Application Publication
(10) Pub. No.: US 2024/0405096 A1
(43) Pub. Date: Dec. 5, 2024

(54) SEMICONDUCTOR DEVICE AND METHOD OF MANUFACTURE

(71) Applicant: Taiwan Semiconductor Manufacturing Co., Ltd., Hsinchu (TW)

(72) Inventors: Yun Chen Teng, New Taipei (TW); Szu-Ying Chen, Hsinchu (TW); Yung-Chung Chen, Hsinchu (TW); Sen-Hong Syue, Zhubei (TW); Chi On Chui, Hsinchu (TW)

(21) Appl. No.: 18/328,207

(22) Filed: Jun. 2, 2023

(51) Int. Cl. H01L 29/66; H01L 21/02; H01L 29/06; H01L 29/423; H01L 29/775

(52) U.S. Cl. CPC H01L 29/66439; H01L 21/02126; H01L 21/02318; H01L 29/0673; H01L 29/42392; H01L 29/775

(57) ABSTRACT

A method includes etching a first trench in a semiconductor substrate to form a first fin and a second fin, and forming a shallow trench isolation (STI) region in the first trench, where forming the STI region includes depositing a first dielectric layer over top surfaces of the first fin and the second fin, and on sidewalls and a bottom surface of the first trench, the first dielectric layer including carbon, depositing a second dielectric layer over the first dielectric layer, and in the first trench, where the second dielectric layer fills the first trench, and performing an anneal process, where the anneal process releases carbon from the first dielectric layer into the second dielectric layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, and 6A are cross-sectional views of intermediate stages in the manufacturing of nano-FETs, in accordance with some embodiments.

FIG. 6B illustrates an example trace of atomic percentage concentration of carbon versus depth of a dielectric layer, after an anneal process is performed.

FIG. 6C is a cross-sectional view of an intermediate stage in the manufacturing of nano-FETs, in accordance with some embodiments.

FIG. 6D is a cross-sectional view of an intermediate stage in the manufacturing of nano-FETs, in accordance with alternate embodiments.

FIGS. 7, 8, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 23C, 24A, 24B, 24C, 25A, 25B, and 25C are cross-sectional views of intermediate stages in the manufacturing of nano-FETs, in accordance with some embodiments.

FIGS. 26A, 26B, and 26C are cross-sectional views of intermediate stages in the manufacturing of fin-FETs, in accordance with alternate embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to the formation of a carbon-rich shallow trench isolation (STI) region. The methods include conformally depositing a first carbon-rich dielectric layer over and in a trench between two adjacent semiconductor fins. A second dielectric layer is then formed over the first dielectric layer to fill the trench between the adjacent fins. An anneal process is performed to convert the second dielectric layer to a third carbon-rich dielectric layer (e.g., an oxide). After the anneal process, an atomic percentage concentration of carbon of the third dielectric layer is in a range from 0.5 percent to 4 percent. Advantageous features of one or more embodiments disclosed herein may allow for the formation of a STI region that comprises the high-quality carbon-rich third dielectric layer that is highly resistant to subsequently performed etching processes (e.g., etching processes that use hydrofluoric acid (HF)). In addition, because the atomic percentage concentration of carbon of the third dielectric layer is in a range from 0.5 percent to 4 percent, lower anneal temperatures can be utilized during the anneal process to convert the second dielectric layer to the third dielectric layer, which allows for thermal budget control for advanced technology nodes that require low total thermal budgets during device fabrication. Further, as a result of being able to utilize lower anneal temperatures for longer durations, improved completeness and conversion efficiency of the second dielectric layer to the third dielectric layer is possible, resulting in the third dielectric layer having a more uniform oxide quality and composition (e.g., at a bottom of the trench) after the conversion process even when the trench has a high aspect ratio.

The embodiments of the present disclosure are discussed in the context of forming a nanostructure (including nanowires, nanosheets, and gate all around) field effect transistor (NSFET), or the like. However, the methods of the present disclosure may be applicable to other types of devices, such as a fin field effect transistor (FinFET) device. In addition, the methods of the present disclosure are not limited to STI regions. For example, various embodiments may be applicable to the formation of inter-layer dielectrics (ILD) and low-k dielectrics.

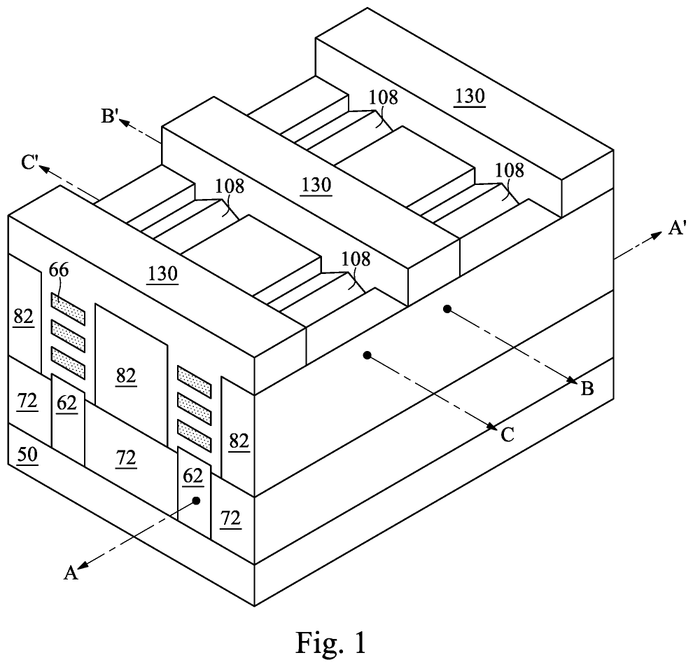

FIG. 1 illustrates an example of nano-FETs (e.g., nanowire FETs, nanosheet FETs, or the like), in accordance with some embodiments. FIG. 1 is a three-dimensional view, where some features of the nano-FETs are omitted for illustration clarity. The nano-FETs may be nanosheet field-effect transistors (NSFETs), nanowire field-effect transistors (NWFETs), gate-all-around field-effect transistors (GAAFETs), or the like.

The nano-FETs include nanostructures 66 (e.g., nanosheets, nanowires, or the like) over semiconductor fins 62 on a substrate 50 (e.g., a semiconductor substrate), with the nanostructures 66 acting as channel regions for the nano-FETs. The nanostructures 66 may include p-type nanostructures, n-type nanostructures, or a combination thereof. Isolation regions 72, such as shallow trench isolation (STI) regions, are disposed between adjacent semiconductor fins 62, which may protrude above and from between adjacent isolation regions 72. Although the isolation regions 72 are described/illustrated as being separate from the substrate 50, as used herein, the term “substrate” may refer to the semiconductor substrate alone or a combination of the semiconductor substrate and one or more additional structures, such as the isolation regions 72. Additionally, although the bottom portions of the semiconductor fins 62 are illustrated as being separate from the substrate 50, the bottom portions of the semiconductor fins 62 may be single, continuous materials with the substrate 50. In this context, the semiconductor fins 62 refer to the portion extending above and from between the adjacent isolation regions 72.

Gate structures 130 are over top surfaces of the semiconductor fins 62 and along top surfaces, sidewalls, and bottom surfaces of the nanostructures 66. Epitaxial source/drain regions 108 are disposed on the semiconductor fins 62 at opposing sides of the gate structures 130. The epitaxial source/drain regions 108 may be shared between various semiconductor fins 62. For example, adjacent epitaxial source/drain regions 108 may be electrically connected, such as through coupling the epitaxial source/drain regions 108 with a same source/drain contact. Source/drain region(s) 108 may refer to a source or a drain, individually or collectively dependent upon the context.

Insulating fins 82, also referred to as hybrid fins or dielectric fins, are disposed over the isolation regions 72, and between adjacent epitaxial source/drain regions 108. The insulating fins 82 block epitaxial growth during the epitaxial source/drain regions 82 formation to prevent coalescing of adjacent epitaxial source/drain regions 108. For example, in some embodiments, the insulating fins 82 may be formed to separate the epitaxial source/drain regions 108 of adjacent transistors.

FIG. 1 further illustrates reference cross-sections that are used in later figures. Cross-section A-A′ is along a longitudinal axis of a semiconductor fin 62 and in a direction of, for example, a current flow between the epitaxial source/drain regions 108 of the nano-FET. Cross-section B-B′ is along a longitudinal axis of a gate structure 130 and in a direction, for example, perpendicular to a direction of current flow between the epitaxial source/drain regions 108 of a nano-FET. Cross-section C-C′ is parallel to cross-section B-B′ and extends through epitaxial source/drain regions 108 of the nano-FETs. Subsequent figures refer to these reference cross-sections for clarity.

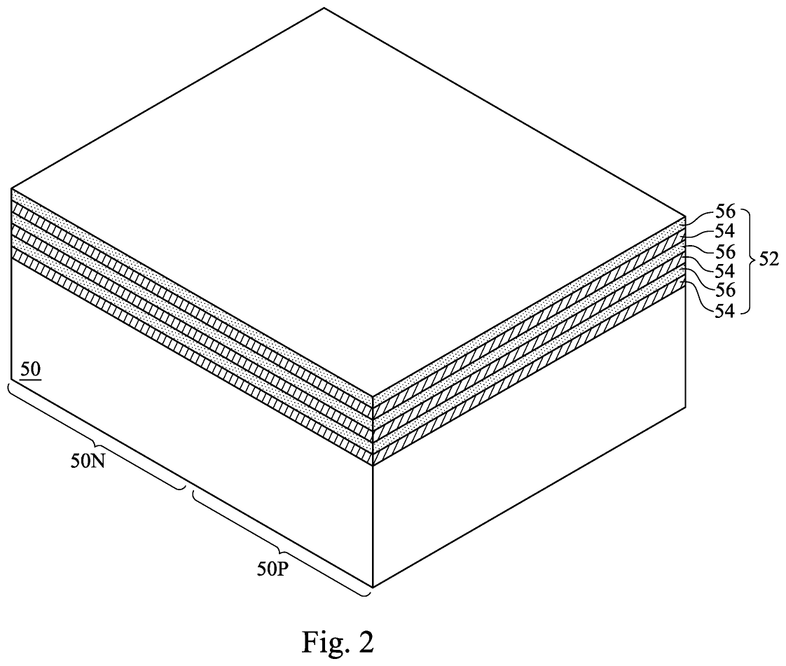

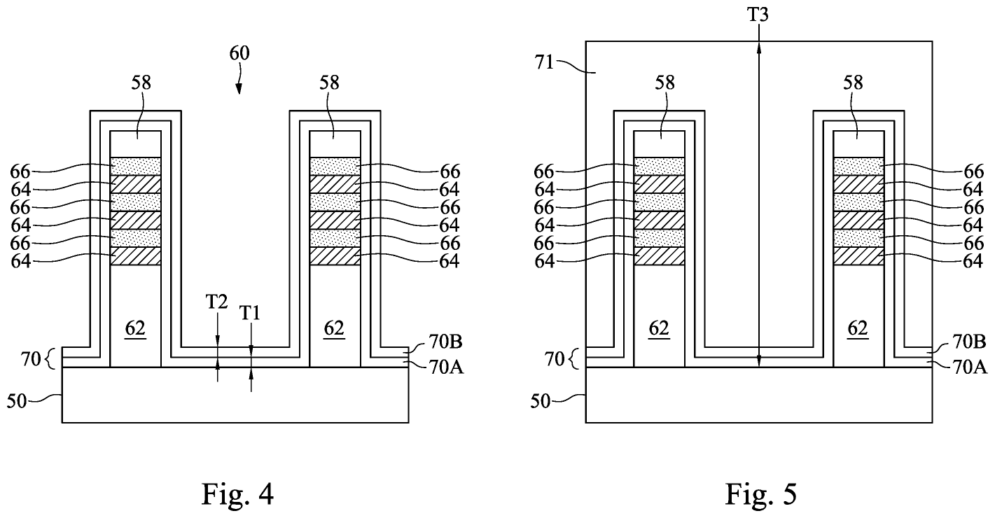

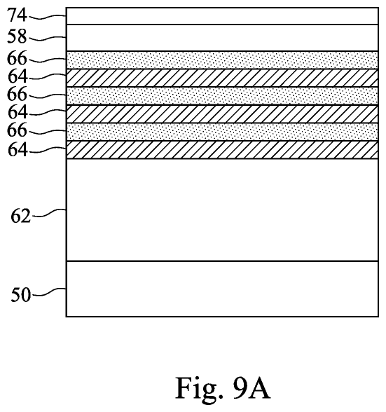

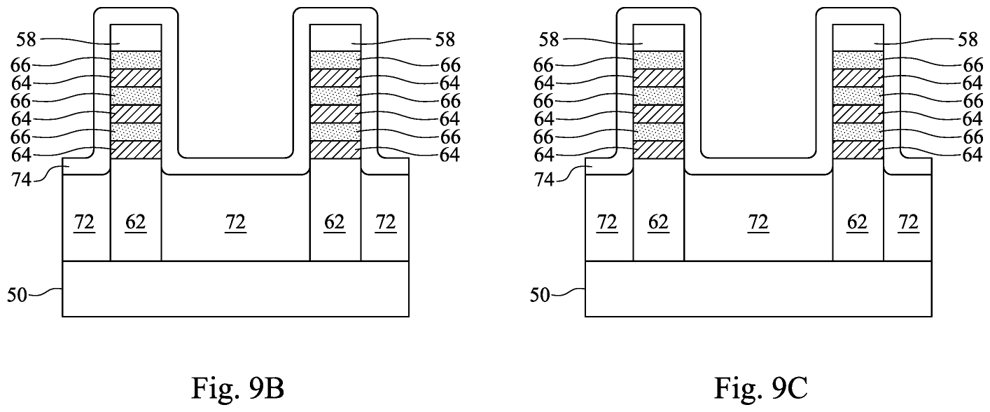

FIGS. 2-6A and FIGS. 6C-25C are views of intermediate stages in the manufacturing of nano-FETs, in accordance with some embodiments. FIGS. 2, 3, and 8 are three-dimensional views. FIGS. 9A, 10A, 11A, 12A, 13A, 14A, 15A, 16A, 17A, 18A, 19A, 20A, 21A, 22A, 23A, 24A, and 25A are cross-sectional views illustrated along a similar cross-section as reference cross-section A-A′ in FIG. 1. FIGS. 4, 5, 6A, 6C, 6D, 7, 9B, 10B, 11B, 12B, 13B, 14B, 15B, 16B, 17B, 18B, 19B, 20B, 21B, 22B, 23B, 24B, and 25B are cross-sectional views illustrated along a similar cross-section as reference cross-section B-B′ in FIG. 1. FIGS. 9C, 10C, 11C, 12C, 13C, 14C, 15C, 16C, 17C, 18C, 19C, 20C, 21C, 22C, 23C, 24C, and 25C are cross-sectional views illustrated along a similar cross-section as reference cross-section C-C′ in FIG. 1.

In FIG. 2, a substrate 50 is provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (not separately illustrated), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

The substrate 50 may be lightly doped with a p-type or an n-type impurity. An anti-punch-through (APT) implantation may be performed on an upper portion of the substrate 50 to form an APT region. During the APT implantation, impurities may be implanted in the substrate 50. The impurities may have a conductivity type opposite from a conductivity type of source/drain regions that will be subsequently formed in each of the n-type region 50N and the p-type region 50P. The APT region may extend under the source/drain regions in the nano-FETs. The APT region may be used to reduce the leakage from the source/drain regions to the substrate 50. In some embodiments, the doping concentration in the APT region is in the range of 10¹⁸ cm⁻³ to 10¹⁹ cm⁻³.

A multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, the multi-layer stack 52 includes three layers of each of the first semiconductor layers 54 and the second semiconductor layers 56. It should be appreciated that the multi-layer stack 52 may include any number of the first semiconductor layers 54 and any number of the second semiconductor layers 56. For example, the multi-layer stack 52 may include from one to ten layers of each of the first semiconductor layers 54 and the second semiconductor layers 56.

In the illustrated embodiment, and as will be subsequently described in greater detail, the first semiconductor layers 54 will be removed and the second semiconductor layers 56 will patterned to form channel regions for the nano-FETs in both the n-type region 50N and the p-type region 50P. The first semiconductor layers 54 are sacrificial layers (or dummy layers), which will be removed in subsequent processing to expose the top surfaces and the bottom surfaces of the second semiconductor layers 56. The first semiconductor material of the first semiconductor layers 54 is a material that has a high etch selectivity from the etching of the second semiconductor layers 56, such as silicon germanium. The second semiconductor material of the second semiconductor layers 56 is a material suitable for both n-type and p-type devices, such as silicon, in some embodiments.

In some embodiments (not separately illustrated), the first semiconductor layers 54 will be patterned to form channel regions for nano-FETs in one region (e.g., the p-type region 50P), and the second semiconductor layers 56 will be patterned to form channel regions for nano-FETs in another region (e.g., the n-type region 50N). For example, the first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like, and the second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etch selectivity from the etching of one another, so that the first semiconductor layers 54 may be removed without removing the second semiconductor layers 56 in the n-type region 50N, and the second semiconductor layers 56 may be removed without removing the first semiconductor layers 54 in the p-type region 50P. Each of the layers may have a small thickness, such as a thickness in a range of 5 nm to 30 nm.

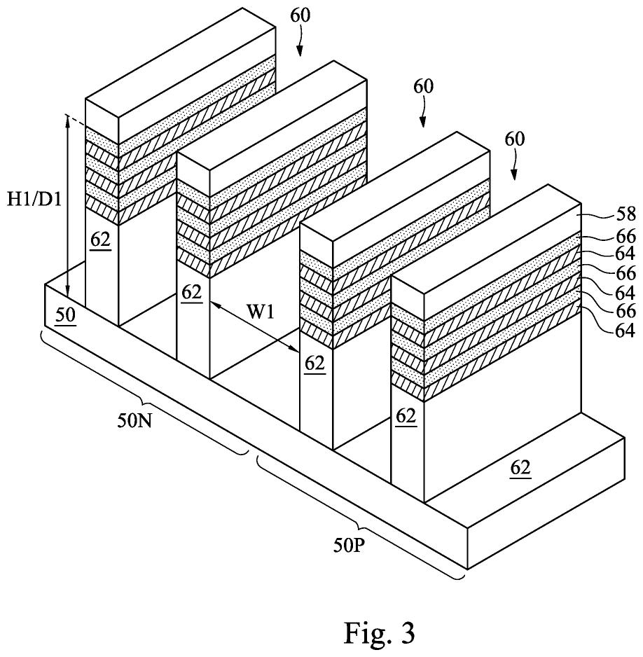

In FIG. 3, trenches 60 are patterned in the substrate 50 and the multi-layer stack 52 to form semiconductor fins 62, nanostructures 64, and nanostructures 66. The semiconductor fins 62 are semiconductor strips patterned in the substrate 50. The nanostructures 64 and the nanostructures 66 include the remaining portions of the first semiconductor layers 54 and the second semiconductor layers 56, respectively. The trenches 60 may be patterned by any acceptable etch process, such as a reactive ion etch (RIE), neutral beam etch (NBE), the like, or a combination thereof. The etching may be anisotropic.

After patterning the trenches 60 in the substrate 50 and the multi-layer stack 52, and when seen from a top-view, a total area of the semiconductor fins 62, the nanostructures 64, and the nanostructures 66 may be equal to a first area. When seen from a top-view, a total area of the trenches 60 may be equal to a second area. A percentage ratio of the first area to the second area (also referred to as the pattern density) may be in a range from 5 percent to 95 percent. In some embodiments, a width W1 between adjacent semiconductor fins 62, between adjacent nanostructures 64, and between adjacent nanostructures 66 may be in a range from 17 nm to 500 nm. In some embodiments, each of the semiconductor fins 62 and the nanostructures 64, 66 vertically above the semiconductor fin 62 may have a combined height H1 that is in a range from 30 nm to 400 nm. For example, in an embodiment, the height H1 may be larger than 200 nm. Additionally, each trench 60 may have a depth D1 that is in a range from 30 nm to 400 nm. For example, in an embodiment, the depth D1 may be larger than 200 nm. Each trench 60 may have an aspect ratio (depth D1/width W1) that is in a range from 2 to 40.

The semiconductor fins 62 and the nanostructures 64, 66 may be patterned by any suitable method. For example, the semiconductor fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as a mask 58 to pattern the semiconductor fins 62 and the nanostructures 64, 66.

In some embodiments, the semiconductor fins 62 and the nanostructures 64, 66 each have widths in a range of 8 nm to 40 nm. In the illustrated embodiment, the semiconductor fins 62 and the nanostructures 64, 66 have substantially equal widths in the n-type region 50N and the p-type region 50P. In some embodiments, the semiconductor fins 62 and the nanostructures 64, 66 in one region (e.g., the n-type region 50N) are wider or narrower than the semiconductor fins 62 and the nanostructures 64, 66 in another region (e.g., the p-type region 50P). Further, while each of the semiconductor fins 62 and the nanostructures 64, 66 are illustrated as having a consistent width throughout, in some embodiments, the semiconductor fins 62 and/or the nanostructures 64, 66 may have tapered sidewalls such that a width of each of the semiconductor fins 62 and/or the nanostructures 64, 66 continuously increases in a direction towards the substrate 50. In such embodiments, each of the nanostructures 64, 66 may have a different width and be trapezoidal in shape.

In FIGS. 4 through 7, STI regions 72 are formed over the substrate 50 and between adjacent semiconductor fins 62, such as in the trenches 60. The STI regions 72 are disposed around at least a portion of the semiconductor fins 62 such that at least a portion of the nanostructures 64, 66 protrude from between adjacent STI regions 72. In the illustrated embodiment, the top surfaces of the STI regions 72 are below the top surfaces of the semiconductor fins 62. In some embodiments, the top surfaces of the STI regions 72 are above or coplanar (within process variations) with the top surfaces of the semiconductor fins 62.

In FIG. 4, dielectric layer 70 is conformally formed over the mask 58, the semiconductor fins 62, the nanostructures 64, 66, and on sidewalls and a bottom surface of the trenches 60. For example, the dielectric layer 70 may be formed on sidewalls of the mask 58, the semiconductor fins 62, and the nanostructures 64, 66. In addition, the dielectric layer 70 may be formed on a top surface of the substrate 50. The dielectric layer 70 may also be referred to subsequently as a dielectric liner. The dielectric layer 70 may have a multi-layer structure and comprise a dielectric layer 70A and a dielectric layer 70B that are formed sequentially over the mask 58, the semiconductor fins 62, the nanostructures 64, 66, and on sidewalls and the bottom surface of the trenches 60. The dielectric layer 70A and the dielectric layer 70B may have different concentrations of carbon. In some embodiments, each of the dielectric layer 70A and the dielectric layer 70B may comprise SiOCN, or the like, and may be deposited by a process such as chemical vapor deposition (CVD), atomic layer deposition (ALD), or the like. Each of the dielectric layer 70A and the dielectric layer 70B is deposited at a process temperature that is in a range from 100° C. to about 800° C. In an embodiment, the dielectric layer 70A may have a thickness T1 that is in a range from 0.5 nm to 10 nm, and the dielectric layer 70B may have a thickness T2 that is in a range from 0.5 nm to 10 nm. Although the dielectric layer 70 is shown as being a bi-layer comprising dielectric layer 70A and dielectric layer 70B, in an embodiment, the dielectric layer 70 may comprise any number of dielectric layers (e.g., one or more layers that each comprise SiOCN, with each layer having a different carbon concentration from the other layers). Using conformal deposition to form the dielectric layer 70 over the mask 58, the semiconductor fins 62, the nanostructures 64, 66, and on the sidewalls and the bottom surface of the trenches 60 enables effective and uniform step coverage of the dielectric layer 70, meaning it can adequately coat features such as the sidewalls and the bottom surfaces of the trenches 60.

The dielectric layer 70A may comprise SiOₓC_{y}N_{z}, where x can be in a range from 0 to 10, y can be in a range from 0 to 10, and z can be in a range from 0 to 10. The composition of the dielectric layer 70A may be graded, such that the dielectric layer 70A is characterized by a gradual variation in composition (e.g., the values of x, y, and z may increase or decrease) with a change of vertical height of the dielectric layer 70A. For example, moving in a vertical direction away from the underlying substrate 50, the values of x, y, and z may gradually increase or gradually decrease.

The dielectric layer 70B may comprise SiOₐC_{b}N_{c}, where a can be in a range from 0 to 10, b can be in a range from 0.1 to 10, and c can be in a range from 0 to 10. The composition of the dielectric layer 70B may be graded, such that the dielectric layer 70B is characterized by a gradual variation in composition (e.g., the values of a, b, and c may increase or decrease) with a change of vertical height of the dielectric layer 70B. For example, moving in a vertical direction away from the underlying substrate 50, the values of a, b, and c may gradually increase or gradually decrease. In an embodiment, the dielectric layer 70A may have a higher carbon content than the dielectric layer 70B. For example, a value of y for the dielectric layer 70A that comprises SiOₓC_{y}N_{z}, is higher than a value of b for the dielectric layer 70B that comprises SiOₐC_{b}N_{c}.

In FIG. 5, a dielectric layer 71 is formed in the trenches 60 and over the dielectric layer 70. The dielectric layer 71 may be formed by a flowable CVD (FCVD) (e.g., a CVD-based material deposition in a remote plasma system and post curing to make it convert to another material, such as an oxide) process, or the like. In an embodiment, the dielectric layer 71 is formed to fill the trenches 60, and excess dielectric material of the dielectric layer 71 is disposed over the mask 58, the semiconductor fins 62, and the nanostructures 64, 66, as well as topmost surfaces of the dielectric layer 70. In an embodiment, the dielectric layer 70 is disposed between and isolates the dielectric layer 71 from the substrate 50, the mask 58, the semiconductor fins 62, and the nanostructures 64, 66. In addition, the dielectric layer 70 is in physical contact with the dielectric layer 71, the substrate 50, the mask 58, the semiconductor fins 62, and the nanostructures 64, 66. In an embodiment, the dielectric layer 71 may have a thickness T3 in the trenches 60 (e.g., from a bottommost surface of the dielectric layer 71 to a topmost surface of the dielectric layer 71) that is in a range from 100 nm to 600 nm.

The FCVD process to form the dielectric layer 71 may comprise exposing surfaces of the trenches 60 and the dielectric layer 70 to a silicon-containing precursor, a nitrogen-containing precursor, and an oxygen-containing precursor. In some embodiments, the silicon-containing precursor is a silylamine, such as trisilylamine (Si₃NH₉), or the like. One or more carrier gases may also be included with the silicon-containing precursor. The carrier gases may include helium (He), argon (Ar), nitrogen (N₂), the like, or a combination thereof.

The nitrogen-containing precursor may include NH₃, or the like. In some embodiments, the nitrogen-containing precursor is activated into plasma in a remote plasma system (RPS) outside of the deposition chamber. The oxygen-containing precursor may include 02, or the like, which may also be activated into plasma in the RPS. Plasma generated in the RPS is carried into the deposition chamber by a carrier gas, which includes He, Ar, N₂, the like, or a combination thereof, in some embodiments.

The silicon-containing precursor, oxygen-containing precursor, and the nitrogen-containing precursor mix and react to deposit the dielectric layer 71 containing silicon, oxygen and nitrogen in the trenches 60 and over the dielectric layer 70. After the formation of the dielectric layer 71, the dielectric layer 71 may be exposed to temperatures in a range from 10° C. to 500° C. to aid in cross-linking and solidifying the dielectric layer 71.

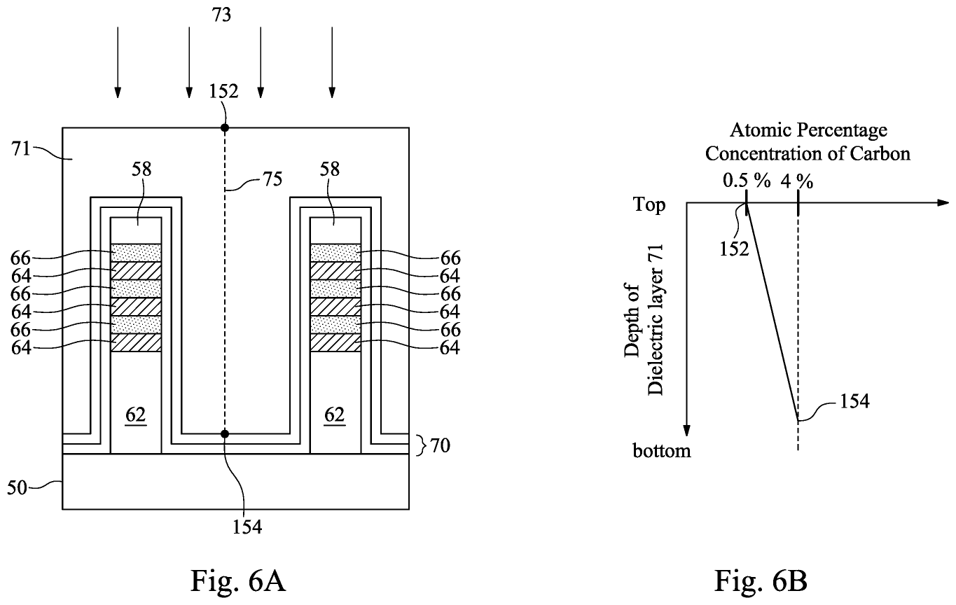

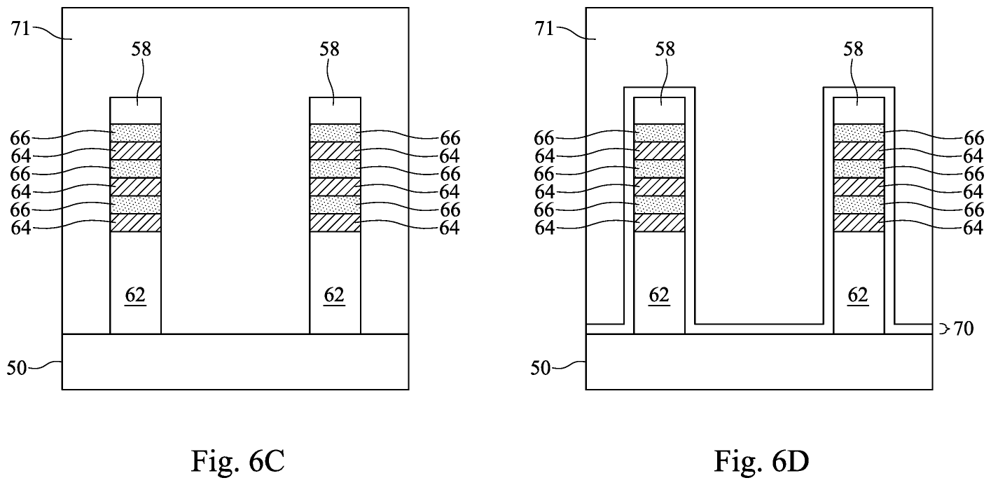

FIG. 6A shows that after exposing the dielectric layer 71 to temperatures in a range from 10° C. to 500° C. to aid in cross-linking and solidifying the dielectric layer 71, an anneal process 73 is then performed to cure or treat the dielectric layer 71, wherein the dielectric layer 71 is converted, such as by an oxidation process. The anneal process 73 can include one or more intermediate anneal steps to convert the dielectric layer 71 to a carbon-rich oxide. The anneal process 73 may include performing the one or more intermediate anneal steps in an oxygen-containing ambient. For example, the one or more intermediate anneal steps of the anneal process 73 may be performed while the dielectric layer 71 is exposed to the oxygen-containing ambient, such as an environment that may include wet steam, H₂ and O₂ gases, hydrogen peroxide (H₂O₂), H₂ and O₂ radicals, O₂ radicals, H₂O radicals, or the like. In an embodiment, each of the intermediate anneal steps may be performed by exposing the dielectric layer 71 to a different oxygen-containing ambient than the oxygen-containing ambients that the dielectric layer 71 is exposed to during the other intermediate anneal steps. During the anneal process 73, the ambient of one or more of the intermediate anneal steps may also comprise other gases, such as N₂, or the like. In some embodiments, the anneal process 73 may be performed at a temperature that is higher than 300° C., and for a duration that is in a range from 0.1 hours to 24 hours. In some embodiments, the anneal process 73 may be performed at a pressure that is in a range from about 0.01 atm to 25 atm. The anneal process 73 can convert the dielectric layer 71 such that after the anneal process 71 is performed, the dielectric layer 71 comprises silicon and oxygen. During the anneal process 73, carbon from the dielectric layer 70 is released or diffuses into the dielectric layer 71, such that after the anneal process 73, the dielectric layer 71 comprises carbon-rich silicon oxide. Because the dielectric layer 71 is disposed over the dielectric layer 70, carbon from the dielectric layer 70 diffuses into the dielectric layer 71 and outgassing of carbon from the dielectric layer 70 into the anneal process chamber is prevented. This is advantageous as it prevents contamination as a result of outgassing that could potentially degrade manufactured device yields and performance.

During the anneal process 73, carbon from the dielectric layer 70 may diffuse or be released into the dielectric layer 71, such that the dielectric layer 70 is partially or fully consumed during the anneal process 73. For example, after the anneal process 73, the dielectric layer 70 may have been fully consumed such that no dielectric layer 70 is present, as shown subsequently in FIG. 6C. In an embodiment, after the anneal process 73, the dielectric layer 70 may be partially consumed such that a thickness of the dielectric layer 70 after the anneal process 73 is smaller than a thickness of the dielectric layer 70 before the anneal process 73, as shown in FIG. 6D. In an embodiment where the dielectric layer 70 comprises the dielectric layer 70A and the dielectric layer 70B, after the anneal process 73, one or both of the dielectric layer 70A and the dielectric layer 70B may be partially or fully consumed.

The anneal process 73 may help to break the Si—N and Si—H bond in the dielectric layer 71 and promote the formation of Si—Si and Si—O bonds, in some embodiments. After the anneal process 73, an atomic percentage concentration of carbon of the dielectric layer 71 is in a range from 0.5 percent to 4 percent. The atomic percentage concentration of carbon in the dielectric layer 71 may be smallest (e.g., 0.5 percent) at a point 152 at a topmost surface of the dielectric layer 71 that is disposed between adjacent semiconductor fins 62. The atomic percentage concentration of carbon in the dielectric layer 71 may be the largest (e.g., 4 percent) at a point 154 at a bottommost surface of the dielectric layer 71 that is disposed between adjacent semiconductor fins 62. The point 152 may be vertically above and overlap the point 154.

FIG. 6B shows an example trace of atomic percentage concentration of carbon of the dielectric layer 71 along the line 75, after the anneal process 73 is performed. It can be seen from FIG. 6B that the atomic percentage concentration of carbon in the dielectric layer 71 is the largest (e.g., 4 percent) at the point 154 at the bottommost surface of the dielectric layer 71, and the atomic percentage concentration of carbon in the dielectric layer 71 may be smallest (e.g., 0.5 percent) at the point 152 at a topmost surface of the dielectric layer 71. The atomic percentage concentration of carbon in the dielectric layer 71 decreases in a vertical direction moving from the point 154 to the point 152.

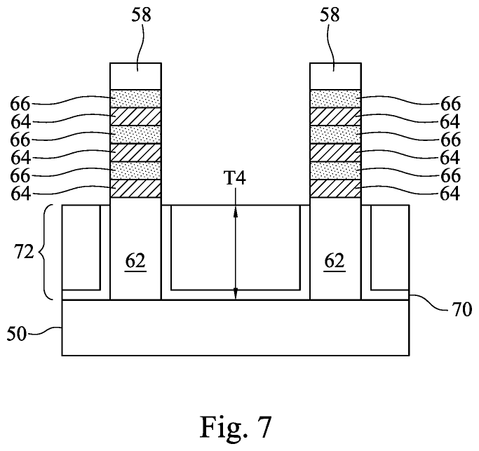

Advantages can be achieved as a result of forming the dielectric layer 70 comprising the dielectric layer 70A and the dielectric layer 70B over the mask 58, the semiconductor fins 62, the nanostructures 64, 66, and on sidewalls and the bottom surface of the trenches 60. Each of the dielectric layer 70A and the dielectric layer 70B comprises SiOCN. The dielectric layer 71 is then formed in the trenches 60 and over the dielectric layer 70, such that the dielectric layer 71 fills the trenches 60. The anneal process 73 is then performed to convert the dielectric layer 71 to an oxide, wherein during the anneal process 73, carbon from the dielectric layer 70 is released or diffuses into the dielectric layer 71. After the anneal process 73, an atomic percentage concentration of carbon of the dielectric layer 71 is in a range from 0.5 percent to 4 percent. Advantageous features of one or more embodiments disclosed herein may allow for the conversion of the dielectric layer 71 to a high-quality carbon-rich oxide layer that is highly resistant to subsequently performed etching processes (e.g., etching processes that use hydrofluoric acid (HF) such as those described below in FIG. 7).

In addition, because during the anneal process 73, carbon from the dielectric layer 70 is released or diffuses into the dielectric layer 71 such that the atomic percentage concentration of carbon of the dielectric layer 71 after the anneal process 73 is in a range from 0.5 percent to 4 percent, lower anneal temperatures can be utilized during the anneal process 73 to convert the dielectric layer 71 to an oxide. This allows for thermal budget control for advanced technology nodes that require low total thermal budgets during device fabrication. Further, when the dielectric layer 71 has an atomic percentage concentration of carbon that is lower than 0.5 percent, the dielectric layer 71 may not be completely converted to an oxide with the lower anneal temperatures of the anneal process 73. Additionally, when the dielectric layer 71 has an atomic percentage concentration of carbon that is greater than 4 percent, the dielectric layer 71 may be excessively resistant to the subsequently performed etching processes (e.g., etching processes that use hydrofluoric acid (HF) such as those described below in FIG. 7 used to form STI regions 72). This would negatively impact the formation of the STI regions 72. Further, as a result of being able to utilize lower anneal temperatures for longer durations, the complete and efficient conversion of the dielectric layer 71 is possible, resulting in the dielectric layer 71 having a more uniform oxide quality and composition (e.g., at a bottom of each trench 60) after the conversion process even when the trench 60 has a high aspect ratio.

In FIG. 7, a removal process is then applied to the dielectric layers 70 and 710 remove excess material over the nanostructures 64, 66. In some embodiments, a planarization process such as a chemical mechanical polish (CMP), an etch-back process, combinations thereof, or the like may be utilized. In some embodiments, the planarization process may expose the mask 58 or remove the mask 58. After the planarization process, the top surfaces of the dielectric layer 70, the dielectric layer 71 and the mask 58 or the nanostructures 64, 66 are coplanar (within process variations). Accordingly, the top surfaces of the mask 58 (if present) or the nanostructures 64, 66 are exposed through the dielectric layer 70. In the illustrated embodiment, the mask 58 remains on the nanostructures 64, 66.

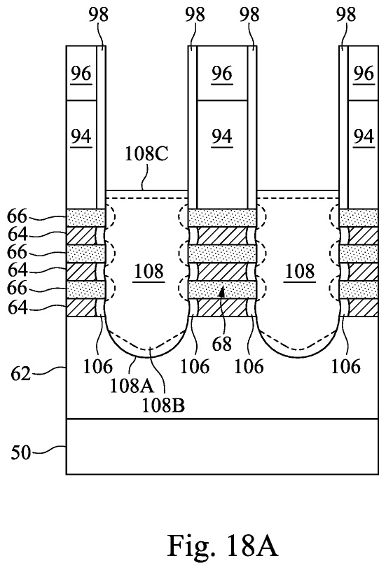

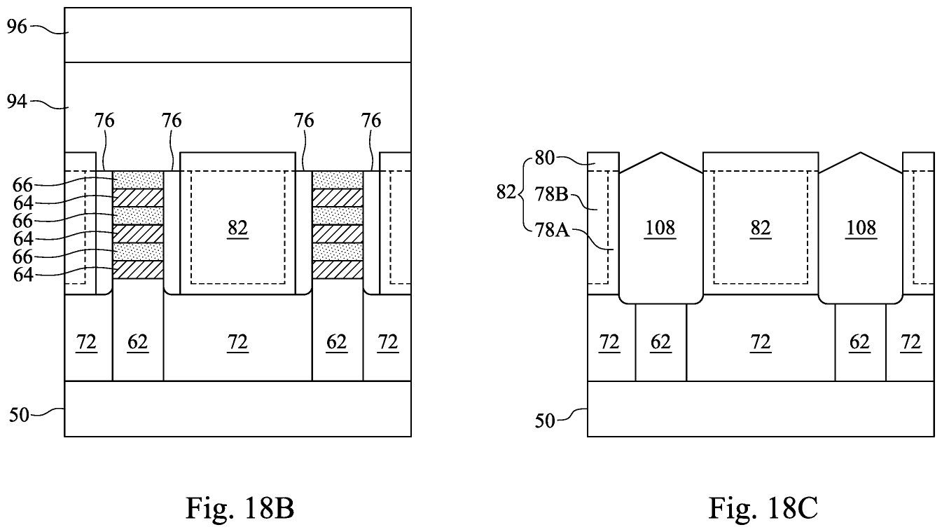

The dielectric layer 70 and the dielectric layer 71 are then recessed to form the STI regions 72, which include remaining portions of the dielectric layers 70 and 71. The dielectric layer 70 and the dielectric layer 71 are recessed such that at least a portion of the nanostructures 64, 66 protrude from between adjacent portions of the dielectric layer 70. Further, the top surfaces of the STI regions 72 may have a flat surface as illustrated, a convex surface, a concave surface (such as dishing), or a combination thereof by applying an appropriate etch. The dielectric layer 70 and the dielectric layer 71 may be recessed using any acceptable etching process, such as one that is selective to the materials of the dielectric layer 70 and the dielectric layer 71 (e.g., selectively etches the materials of the dielectric layer 70 and the dielectric layer 71 at a faster rate than the materials of the semiconductor fins 62 and the nanostructures 64, 66). For example, an oxide removal may be performed using dilute hydrofluoric (dHF) acid as an etchant. In an embodiment, after the dielectric layer 70 and the dielectric layer 71 are recessed to form the STI regions 72, the STI regions 72 may have a thickness T4 in the trenches 60 (e.g., from a bottommost surface of the STI regions 72 to a topmost surface of the STI regions 72) that is in a range from 160 nm to 20 nm. In an embodiment, a ratio between the thickness T3 of the dielectric layer 71 and the thickness T4 of the STI regions 72 is in a range from 25 to 1.5. In an embodiment, a ratio between the combined height H1 of each semiconductor fin 62 and the nanostructures 64, 66 vertically above the semiconductor fin 62, and the thickness T4 may be in a range from 15 to 1.2. The dielectric layer 70 may not be shown in subsequent Figures. As described above in FIG. 6A, the dielectric layer 71 is converted to a high-quality carbon-rich oxide layer that is highly resistant to etching processes that use hydrofluoric acid (HF). Because of this, advantages can be achieved. For example, during the recessing of the dielectric layer 70 and the dielectric layer 71 to form the STI regions 72, a reduced amount of the dielectric layer 71 is removed (also referred to as oxide loss), which allows the remaining STI regions 72 to adequately protect sidewalls of the semiconductor fins 62. For example, during a subsequent process to form epitaxial source/drain regions 108 (described subsequently in FIGS. 18A-18C), epitaxial source/drain regions 108 formed in adjacent semiconductor fins 62 are adequately isolated from each other and prevented from merging with each other by the STI region 72. As a result, device performance can be improved.

The process previously described in FIGS. 2-7 is just one example of how the semiconductor fins 62 and the nanostructures 64, 66 may be formed. In some embodiments, the semiconductor fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductor fins 62 and/or the nanostructures 64, 66. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the nanostructures 64, 66, the semiconductor fins 62, and/or the substrate 50. The wells may have a conductivity type opposite from a conductivity type of source/drain regions that will be subsequently formed in each of the n-type region 50N and the p-type region 50P. In some embodiments, a p-type well is formed in the n-type region 50N, and an n-type well is formed in the p-type region 50P. In some embodiments, a p-type well or an n-type well is formed in both the n-type region 50N and the p-type region 50P.

In embodiments with different well types, different implant steps for the n-type region 50N and the p-type region 50P may be achieved using mask (not separately illustrated) such as a photoresist. For example, a photoresist may be formed over the semiconductor fins 62, the nanostructures 64, 66, and the STI regions 72 in the n-type region 50N. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in the range of 10¹³ cm⁻³ to 10¹⁴ cm⁻³. After the implant, the photoresist may be removed, such as by any acceptable ashing process.

Following or prior to the implanting of the p-type region 50P, a mask (not separately illustrated) such as a photoresist is formed over the semiconductor fins 62, the nanostructures 64, 66, and the STI regions 72 in the p-type region 50P. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in the range of 10¹³ cm⁻³ to 10¹⁴ cm⁻³. After the implant, the photoresist may be removed, such as by any acceptable ashing process.

After the implants of the n-type region 50N and the p-type region 50P, an anneal may be performed to repair implant damage and to activate the p-type and/or n-type impurities that were implanted. In some embodiments where epitaxial structures are epitaxially grown for the semiconductor fins 62 and/or the nanostructures 64, 66, the grown materials may be in situ doped during growth, which may obviate the implantations, although in situ and implantation doping may be used together.

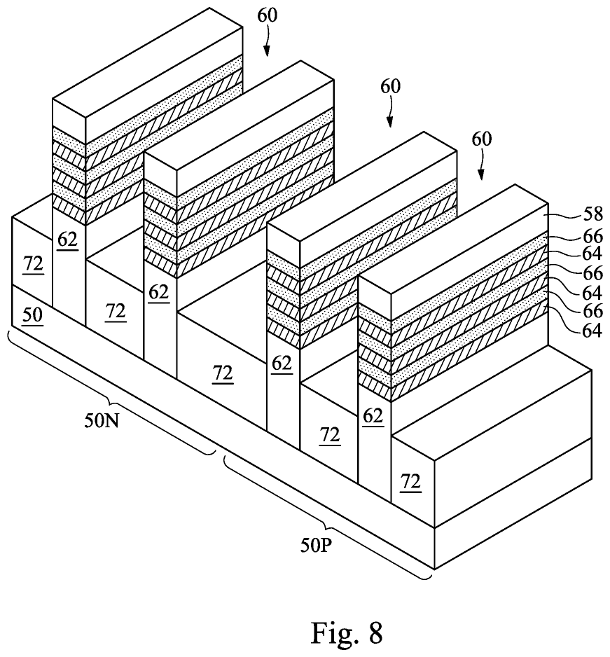

FIG. 8 illustrates a three-dimensional view of the structure shown previously in FIG. 7, after the dielectric layer 70 and the dielectric layer 71 are recessed to form the STI regions 72.

FIGS. 9A-25C illustrate various additional steps in the manufacturing of embodiment devices. FIGS. 9A-25C illustrate features in either of the n-type region 50N and the p-type region 50P. For example, the structures illustrated may be applicable to both the n-type region 50N and the p-type region 50P. Differences (if any) in the structures of the n-type region 50N and the p-type region 50P are described in the text accompanying each figure. As will be subsequently described in greater detail, insulating fins 82 will be formed between the semiconductor fins 62. FIGS. 9A, 10A, 11A, 12A, 13A, 14A, 15A, 16A 17A, 18A, 19A, 20A, 21A, 22A, 23A, 24A, and 25A illustrate a semiconductor fin 62 and structures formed on it. FIGS. 9B, 9C, 10B, 10C, 11B, 11C, 12B, 12C, 13B, 13C, 14B, 14C, 15B, 15C, 16B, 16C, 17B, 17C, 18B, 18C, 19B, 19C, 20B, 20C, 21B, 21C, 22B, 22C, 23B, 23C, 24B, 24C, 25B, and 25C each illustrate two semiconductor fins 62 and portions of the insulating fins 82 and the STI regions 72 that are disposed between the two semiconductor fins 62 in the respective cross-sections.

In FIGS. 9A-C, a sacrificial layer 74 is conformally formed over the mask 58, the semiconductor fins 62, the nanostructures 64, 66, and the STI regions 72. The sacrificial layer 74 may be formed of a semiconductor material (such as one selected from the candidate semiconductor materials of the substrate 50), which may be grown by a process such as vapor phase epitaxy (VPE) or molecular beam epitaxy (MBE), deposited by a process such as chemical vapor deposition (CVD) or atomic layer deposition (ALD), or the like. For example, the sacrificial layer 74 may be formed of silicon or silicon germanium.

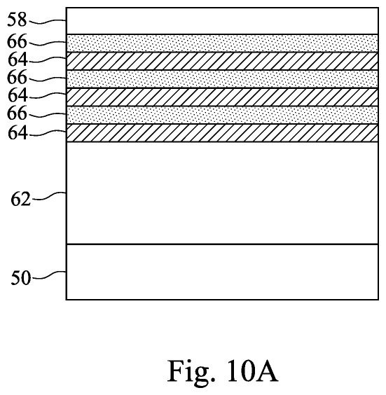

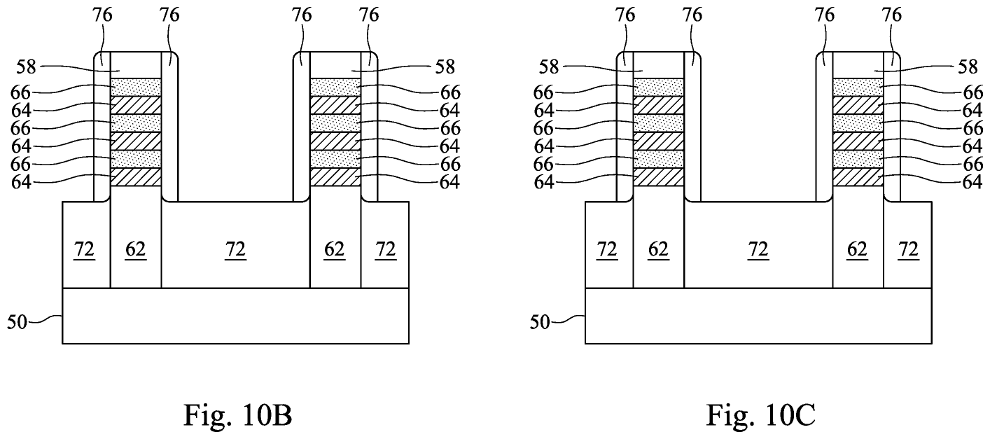

In FIGS. 10A-C, the sacrificial layer 74 is patterned to form sacrificial spacers 76 using an etching process, such as a dry etch, a wet etch, or a combination thereof. The etching process may be anisotropic. As a result of the etching process, the portions of the sacrificial layer 74 over the mask 58 and the nanostructures 64, 66 are removed, and the STI regions 72 between the nanostructures 64, 66 are partially exposed. The sacrificial spacers 76 are disposed over the STI regions 72 and are further disposed on the sidewalls of the mask 58, the semiconductor fins 62, and the nanostructures 64, 66.

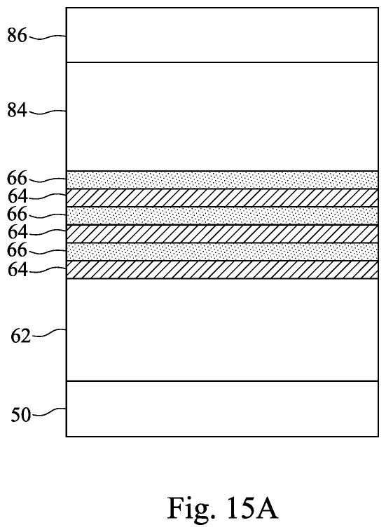

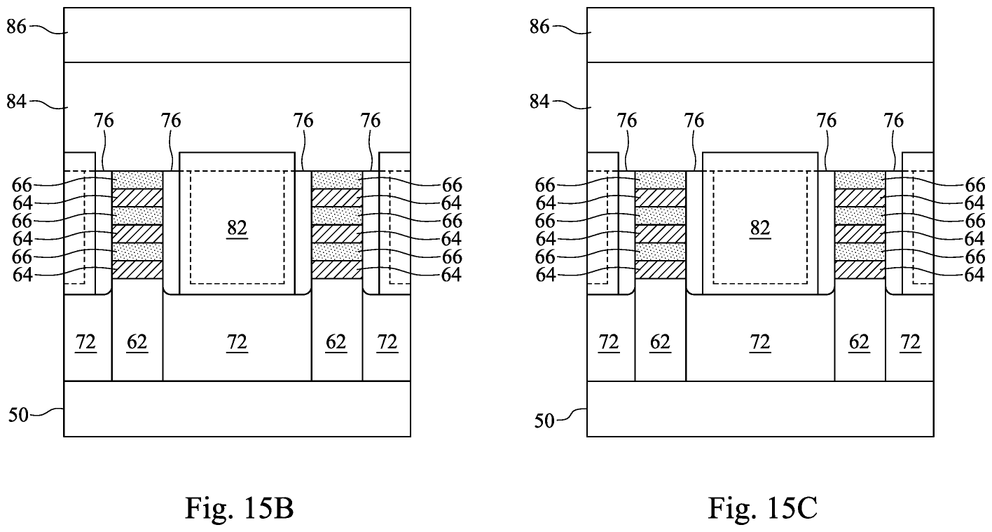

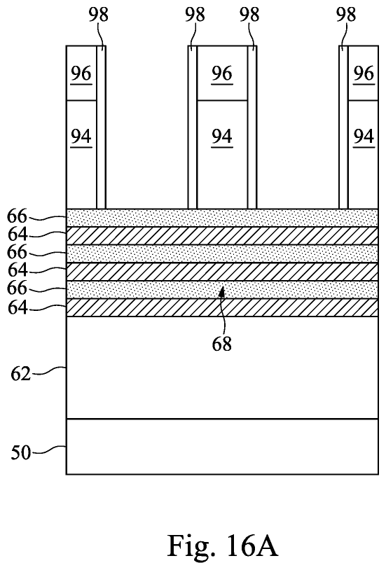

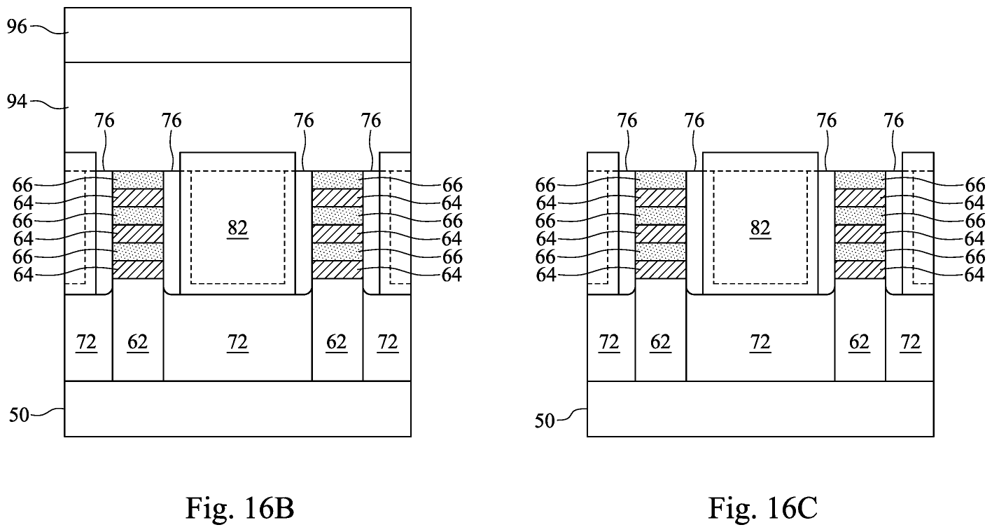

In subsequent process steps, a dummy gate layer 84 may be deposited over portions of the sacrificial spacers 76 (see below, FIGS. 15A-C), and the dummy gate layer 84 may be patterned to provide dummy gates 94 that include underlying portions of the sacrificial spacers 76 (see below, FIGS. 16A-C). These dummy gates 94 (e.g., patterned portions of the dummy gate layer 84 and portions of the sacrificial spacers 76) may then be replaced with a functional gate stack. Specifically, the sacrificial spacers 76 are used as temporary spacers during processing to delineate boundaries of insulating fins, and the sacrificial spacers 76 and the nanostructures 64 will be subsequently removed and replaced with gate structures that are wrapped around the nanostructures 66. The sacrificial spacers 76 are formed of a material that has a high etch selectivity from the etching of the material of the nanostructures 66. For example, the sacrificial spacers 76 may be formed of the same semiconductor material as the nanostructures 64 so that the sacrificial spacers 76 and the nanostructures 64 may be removed in a single process step. Alternatively, the sacrificial spacers 76 may be formed of a different material as the nanostructures 64.

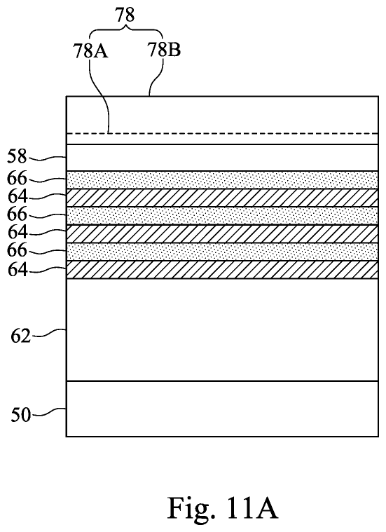

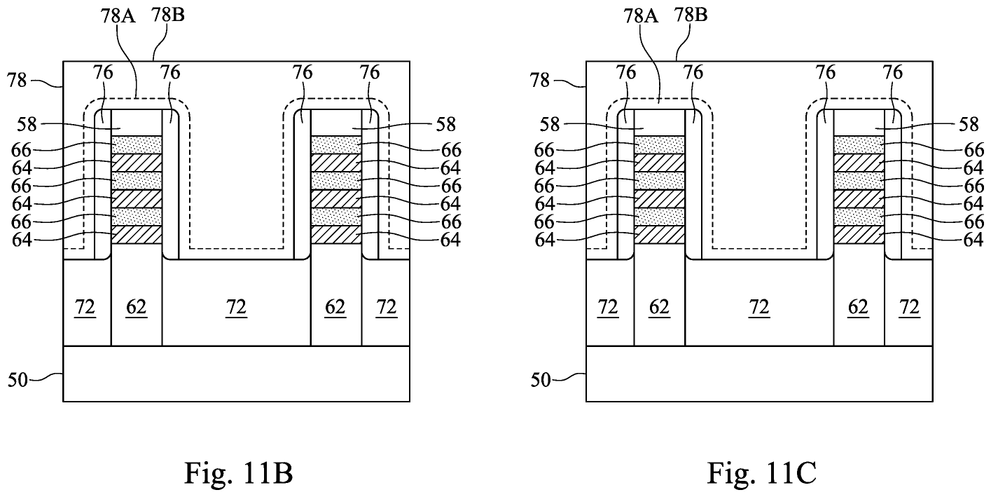

FIGS. 11A through 13C illustrate a formation of insulating fins 82 (also referred to as hybrid fins or dielectric fins) between the sacrificial spacers 76 adjacent to the semiconductor fins 62 and nanostructures 64, 66. The insulating fins 82 may insulate and physically separate subsequently formed source/drain regions (see below, FIGS. 18A-C) from each other.

In FIGS. 11A-C, a liner 78A and a fill material 78B are formed over the structure. As discussed in greater detail below, the liner 78A and the fill material 78B will be patterned and collectively form portions of the insulating fins 82. The liner 78A is conformally deposited over exposed surfaces of the STI regions 72, the masks 58, the semiconductor fins 62, the nanostructures 64, 66, and the sacrificial spacers 76 by an acceptable deposition process such as atomic layer deposition (ALD), chemical vapor deposition (CVD), physical vapor deposition (PVD), or the like. The liner 78A may be formed of one or more dielectric material(s) having a high etch selectivity from the etching of the semiconductor fins 62, the nanostructures 64, 66, and the sacrificial spacers 76, e.g. a nitride such as silicon nitride, silicon carbonitride, silicon oxycarbonitride, or the like. The liner 78A may reduce oxidation of the sacrificial spacers 76 during the subsequent formation of the fill material 78B, which may be useful for a subsequent removal of the sacrificial spacers 76.

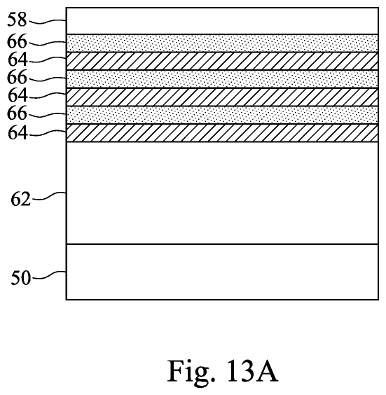

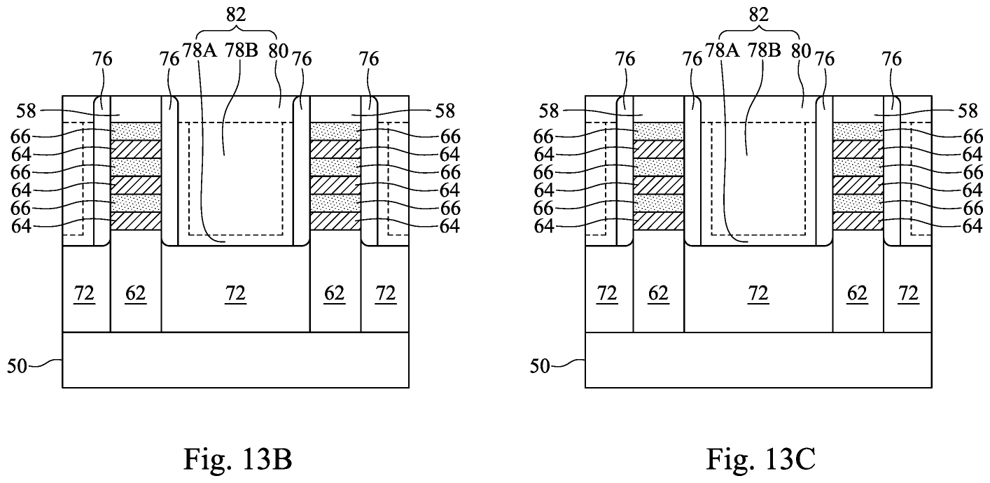

Next, a fill material 78B is formed over the liner 78A, filling the remaining area between the semiconductor fins 62 and the nanostructures 64, 66 that is not filled by the sacrificial spacers 76 or the liner 78A. The fill material 78B may form the bulk of the lower portions of the insulating fins 82 (see FIGS. 13A-C) to insulate subsequently formed source/drain regions (see FIG. 18C) from each other. The fill material 78B may be formed by an acceptable deposition process such as ALD, CVD, PVD, or the like. The fill material 78B may be formed of one or more dielectric material(s) having a high etch selectivity from the etching of the semiconductor fins 62, the nanostructures 64, 66, the sacrificial spacers 76, and the liner 78A such as an oxide such as silicon oxide, silicon oxynitride, silicon oxycarbonitride, silicon oxycarbide, the like, or combinations thereof.

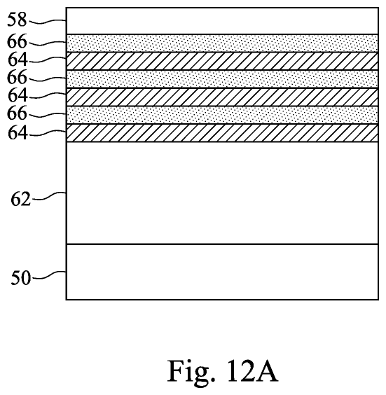

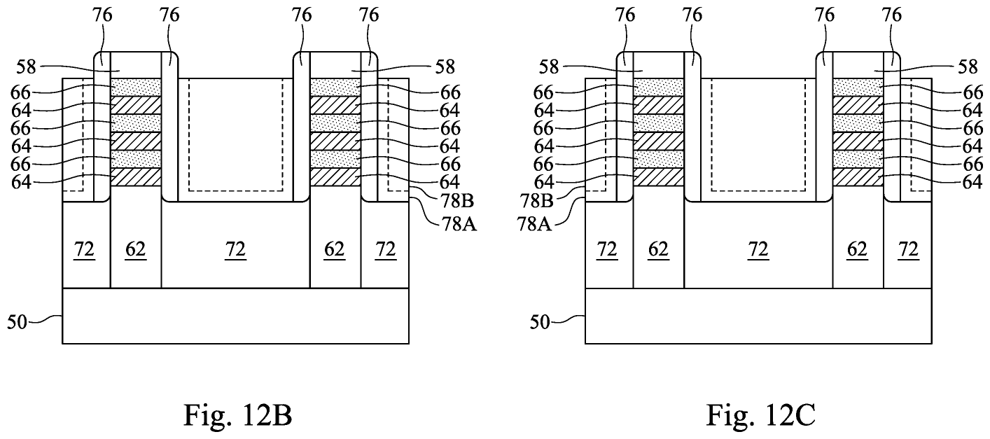

In FIGS. 12A-12C, upper portions of the liner 78A and the fill material 78B above top surfaces of the masks 58 may be removed using one or more acceptable planarization and/or etching processes. The etching process may be selective to the liner 78A and to the fill material 78B (e.g., selectively etches the liner 78A and the fill material 78B at a faster rate than the sacrificial spacers 76 and/or the mask 58). After etching, top surfaces of the liner 78A and the fill material 78B may be below top surfaces of the mask 58. In other embodiments, the fill material 78 may be recessed below top surfaces of the mask 58 while the liner 78A is maintained at a same level as the mask 58.

FIGS. 13A-C illustrate the forming of a dielectric capping layer 80 on the liner 78A and the fill material 78B, thereby forming the insulating fins 82. The dielectric capping layer 80 may fill a remaining area over the liner 78A, over the fill material 78B, and between sidewalls of the mask 58. The dielectric capping layer 80 may be formed by an acceptable deposition process such as ALD, CVD, PVD, or the like. The dielectric capping layer 80 may be formed of one or more dielectric material(s) having a high etch selectivity from the etching of the semiconductor fins 62, the nanostructures 64, 66, the sacrificial spacers 76, the liner 78A, and the fill material 78B. For example, the dielectric capping layer 80 may comprise a high-k material such as hafnium oxide, zirconium oxide, zirconium aluminum oxide, hafnium aluminum oxide, hafnium silicon oxide, aluminum oxide, the like, or combinations thereof. In this way, the dielectric capping layer 80 may serve as a hard mask that protects the underlying dielectric liner 78A and the fill material 78B from over etch in subsequent processes.

The dielectric capping layer 80 may be formed to initially cover the mask 58 and the nanostructures 64, 66. Subsequently, a removal process is applied to remove excess material(s) of the dielectric capping layer 80. In some embodiments, a planarization process such as a CMP, an etch-back process, combinations thereof, or the like may be utilized. The planarization process exposes the masks 58 such that top surfaces of the masks 58, the sacrificial spacers 76, and the dielectric capping layer 80 are coplanar (within process variations). In the illustrated embodiment, the masks 58 remain after the planarization process. In some embodiments, portions of or the entirety of the masks 58 may also be removed by the planarization process.

As a result, insulating fins 82 are formed between and contacting the sacrificial spacers 76. The insulating fins 82 comprise the liner 78A, the fill material 78B, and the dielectric capping layer 80. The sacrificial spacers 76 space the insulating fins 82 apart from the nanostructures 64, 66, and a size of the insulating fins 82 may be adjusted by adjusting a thickness of the sacrificial spacers 76.

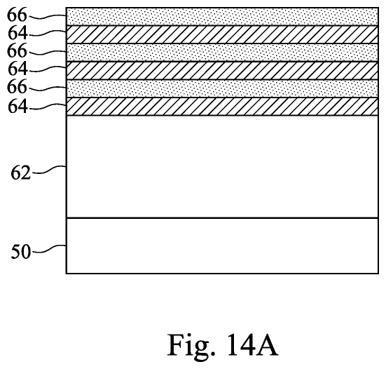

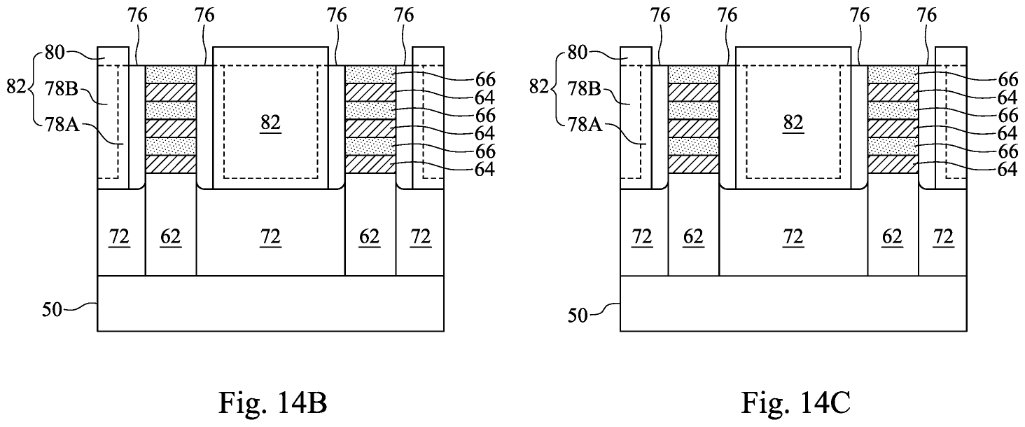

In FIGS. 14A-C, the mask 58 is removed using an etching process, for example. The etching process may be a wet etch that selectively removes the mask 58 without significantly etching the insulating fins 82. The etching process may be anisotropic. Further, the etching process (or a separate, selective etching process) may also be applied to reduce a height of the sacrificial spacers 76 to a similar level (e.g., same within processing variations) as the stacked nanostructures 64, 66. After the etching process(es), a topmost surface of the stacked nanostructures 64, 66 and the sacrificial spacers 76 may be exposed and may be lower than a topmost surface of the insulating fins 82.

In FIG. 15A-C, a dummy gate layer 84 is formed on the insulating fins 82, the sacrificial spacers 76, and the nanostructures 64, 66. Because the nanostructures 64, 66 and the sacrificial spacers 76 extend lower than the insulating fins 82, the dummy gate layer 84 may be disposed along exposed sidewalls of the insulating fins 82. The dummy gate layer 84 may be deposited and then planarized, such as by a CMP. The dummy gate layer 84 may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer 84 may also be formed of a semiconductor material (such as one selected from the candidate semiconductor materials of the substrate 50), which may be grown by a process such as vapor phase epitaxy (VPE) or molecular beam epitaxy (MBE), deposited by a process such as chemical vapor deposition (CVD) or atomic layer deposition (ALD), or the like. The dummy gate layer 84 may be formed of material(s) that have a high etch selectivity from the etching of insulation materials, e.g., the insulating fins 82. A mask layer 86 may be deposited over the dummy gate layer 84. The mask layer 86 may be formed of one or more dielectric material layers, such as silicon nitride, silicon oxynitride, or the like. In this example, a single dummy gate layer 84 and a single mask layer 86 are formed across the n-type region 50N and the p-type region 50P.

In FIGS. 16A-16C, the mask layer 86 is patterned using acceptable photolithography and etching techniques to form masks 96. The pattern of the masks 96 is then transferred to the dummy gate layer 84 by any acceptable etching technique to form dummy gates 94. The dummy gates 94 covers the top surface of the nanostructures 64, 66 that will be used to form channel regions. The pattern of the masks 96 may be used to physically separate adjacent dummy gates 94. The dummy gates 94 may also have lengthwise directions substantially perpendicular (within process variations) to the lengthwise directions of the semiconductor fins 62. The masks 96 can optionally be removed after patterning, such as by any acceptable etching technique.

The sacrificial spacers 76 and the dummy gates 94 collectively extend along the portions of the nanostructures 66 that will be patterned to form channel regions 68. Subsequently formed gate structures will replace the sacrificial spacers 76 and the dummy gates 94.

As noted above, the dummy gates 94 may be formed of a semiconductor material. In such embodiments, the nanostructures 64, the sacrificial spacers 76, and the dummy gates 94 are each formed of semiconductor materials. In some embodiments, the nanostructures 64 and the sacrificial spacers 76 are formed of a first semiconductor material (e.g., silicon germanium) and the dummy gates 94 are formed of a second semiconductor material (e.g., silicon), so that during a replacement gate process, the dummy gates 94 may be removed in a first etching step, and the nanostructures 64 and the sacrificial spacers 76 may be removed together in a second etching step. When the nanostructures 64 and the sacrificial spacers 76 are formed of silicon germanium: the nanostructures 64 and the sacrificial spacers 76 may have similar germanium concentrations, the nanostructures 64 may have a greater germanium concentration than the sacrificial spacers 76, or the sacrificial spacers 76 may have a greater germanium concentration than the nanostructures 64. In some embodiments, the nanostructures 64 are formed of a first semiconductor material (e.g., silicon germanium) and the sacrificial spacers 76 and the dummy gates 94 are formed of a second semiconductor material (e.g., silicon), so that during a replacement gate process, the sacrificial spacers 76 and the dummy gates 94 may be removed together in a first etching step, and the nanostructures 64 may be removed in a second etching step.

Gate spacers 98 are formed over the nanostructures 64, 66, and on exposed sidewalls of the masks 96 (if present) and the dummy gates 94. The gate spacers 98 may be formed by conformally depositing one or more dielectric material(s) on the dummy gates 94 and subsequently etching the dielectric material(s). Acceptable dielectric materials may include silicon oxide, silicon nitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 94 (thus forming the gate spacers 98). After etching, the gate spacers 98 can have curved sidewalls or can have straight sidewalls.

Further, implants may be performed to form lightly doped source/drain (LDD) regions (not separately illustrated). In the embodiments with different device types, similar to the implants for the wells previously described, a mask (not separately illustrated) such as a photoresist may be formed over the n-type region 50N, while exposing the p-type region 50P, and appropriate type (e.g., p-type) impurities may be implanted into the semiconductor fins 62 and/or the nanostructures 64, 66 exposed in the p-type region 50P. The mask may then be removed. Subsequently, a mask (not separately illustrated) such as a photoresist may be formed over the p-type region 50P while exposing the n-type region 50N, and appropriate type impurities (e.g., n-type) may be implanted into the semiconductor fins 62 and/or the nanostructures 64, 66 exposed in the n-type region 50N. The mask may then be removed. The n-type impurities may be any of the n-type impurities previously described, and the p-type impurities may be any of the p-type impurities previously described. During the implanting, the channel regions 68 remain covered by the dummy gates 94, so that the channel regions 68 remain substantially free of the impurity implanted to form the LDD regions. The LDD regions may have a concentration of impurities in the range of 10¹⁵ cm⁻³ to 10¹⁹ cm⁻³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

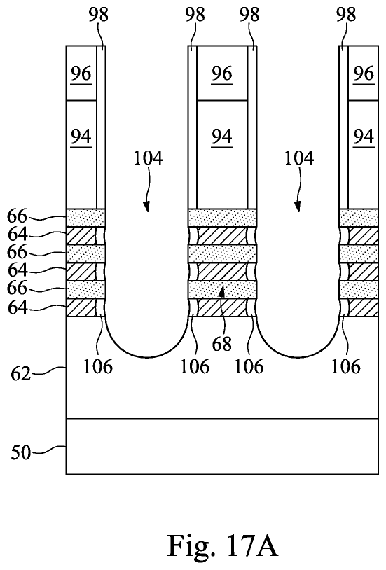

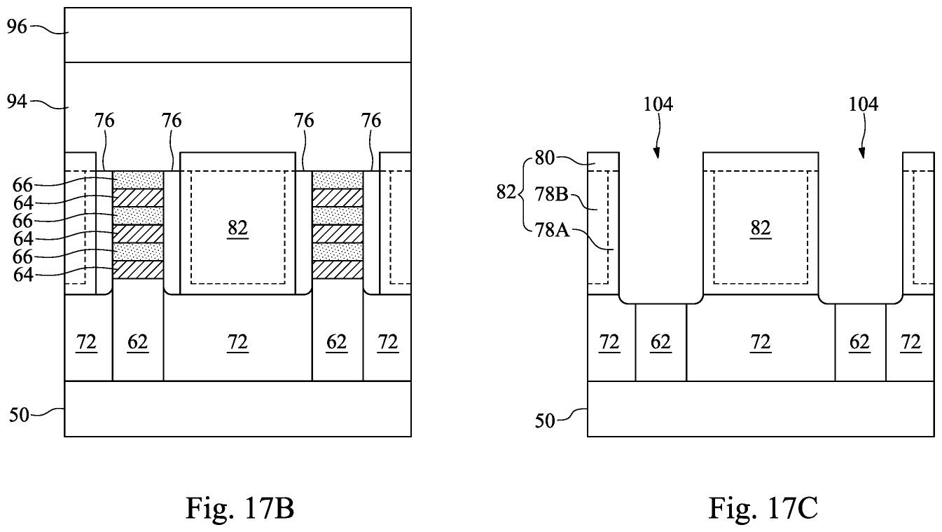

In FIGS. 17A-C, source/drain recesses 104 are formed in the nanostructures 64, 66 and the sacrificial spacers 76. In the illustrated embodiment, the source/drain recesses 104 extend through the nanostructures 64, 66 and the sacrificial spacers 76 into the semiconductor fins 62. The source/drain recesses 104 may also extend into the substrate 50. In various embodiments, the source/drain recesses 104 may extend to a top surface of the substrate 50 without etching the substrate 50; the semiconductor fins 62 may be etched such that bottom surfaces of the source/drain recesses 104 are disposed below the top surfaces of the STI regions 72; or the like. The source/drain recesses 104 may be formed by etching the nanostructures 64, 66 and the sacrificial spacers 76 using an anisotropic etching processes, such as a RIE, a NBE, or the like. The gate spacers 98 and the dummy gates 94 collectively mask portions of the semiconductor fins 62 and/or the nanostructures 64, 66 in the channel region during the etching processes used to form the source/drain recesses 104. A single etch process may be used to etch the nanostructures 64, 66 and the sacrificial spacers 76, or multiple etch processes may be used to etch the nanostructures 64, 66 and the sacrificial spacers 76 individually. Timed etch processes may be used to stop the etching of the source/drain recesses 104 after the source/drain recesses 104 reach a desired depth.

In FIGS. 18A-C inner spacers 106 are formed on the sidewalls of the nanostructures 64, e.g., those sidewalls exposed by the source/drain recesses 104, and epitaxial source/drain regions 108 are formed in the source/drain recesses 104 as illustrated in FIGS. 18A-C. As will be subsequently described in greater detail, source/drain regions will be subsequently formed in the source/drain recesses 104, and the nanostructures 64 will be subsequently replaced with corresponding gate structures. The inner spacers 106 act as isolation features between the subsequently formed source/drain regions and the subsequently formed gate structures. Further, the inner spacers 106 may be used to substantially prevent damage to the subsequently formed source/drain regions by subsequent etching processes, such as etching processes used to subsequently remove the nanostructures 64.

As an example to form the inner spacers 106, the source/drain recesses 104 can be laterally expanded. Specifically, portions of the sidewalls of the nanostructures 64 exposed by the source/drain recesses 104 may be recessed. Although sidewalls of the nanostructures 64 are illustrated as being concave, the sidewalls may be straight or convex. The sidewalls may be recessed by any acceptable etching process, such as one that is selective to the nanostructures 64 (e.g., selectively etches the materials of the nanostructures 64 at a faster rate than the material of the nanostructures 66). The etching may be isotropic. For example, when the nanostructures 66 are formed of silicon and the nanostructures 64 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. The inner spacers 106 are then formed on the recessed sidewalls of the nanostructures 64. The inner spacers 106 can be formed by conformally forming an insulating material and subsequently etching the insulating material. The insulating material may be silicon nitride or silicon oxynitride, although any suitable material, such as a low-k dielectric material, may be utilized. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 106 are illustrated as being recessed with respect to the sidewalls of the gate spacers 98, the outer sidewalls of the inner spacers 106 may extend beyond or be flush with the sidewalls of the gate spacers 98. In other words, the inner spacers 106 may partially fill, completely fill, or overfill the sidewall recesses. Moreover, although the sidewalls of the inner spacers 106 are illustrated as being concave, the sidewalls of the inner spacers 106 may be straight or convex.

The epitaxial source/drain regions 108 are formed in recesses 104 such that each dummy gate 94 (and corresponding channel region 68) is disposed between respective adjacent pairs of the epitaxial source/drain regions 108. In some embodiments, the gate spacers 98 and the inner spacers 106 are used to separate the epitaxial source/drain regions 108 from, respectively, the dummy gates 94 and the nanostructures 64 by an appropriate lateral distance so that the epitaxial source/drain regions 108 do not short out with subsequently formed gates of the resulting nano-FETs. A material of the epitaxial source/drain regions 108 may be selected to exert stress in the respective channel regions 68, thereby improving performance.

The epitaxial source/drain regions 108 in the n-type region 50N may be formed by masking the p-type region 50P. Then, the epitaxial source/drain regions 108 in the n-type region 50N are epitaxially grown in the source/drain recesses 104 in the n-type region 50N. The epitaxial source/drain regions 108 may include any acceptable material appropriate for n-type devices. For example, if the nanostructures 66 are silicon, the epitaxial source/drain regions 108 in the n-type region 50N may include materials exerting a tensile strain on the channel regions 68, such as silicon, silicon carbide, phosphorous doped silicon carbide, silicon arsenide, silicon phosphide, or the like. The epitaxial source/drain regions 108 in the n-type region 50N may be referred to as “n-type source/drain regions.” The epitaxial source/drain regions 108 in the n-type region 50N may have surfaces raised from respective surfaces of the semiconductor fins 62 and the nanostructures 64, 66, and may have facets.

The epitaxial source/drain regions 108 in the p-type region 50P may be formed by masking the n-type region 50N. Then, the epitaxial source/drain regions 108 in the p-type region 50P are epitaxially grown in the source/drain recesses 104 in the p-type region 50P. The epitaxial source/drain regions 108 may include any acceptable material appropriate for p-type devices. For example, if the nanostructures 66 are silicon, the epitaxial source/drain regions 108 in the p-type region 50P may include materials exerting a compressive strain on the channel regions 68, such as silicon germanium, boron doped silicon germanium, silicon germanium phosphide, germanium, germanium tin, or the like. The epitaxial source/drain regions 108 in the p-type region 50P may be referred to as “p-type source/drain regions.” The epitaxial source/drain regions 108 in the p-type region 50P may have surfaces raised from respective surfaces of the semiconductor fins 62 and the nanostructures 64, 66, and may have facets.

The epitaxial source/drain regions 108, the nanostructures 64, 66, and/or the semiconductor fins 62 may be implanted with impurities to form source/drain regions, similar to the process previously described for forming LDD regions, followed by an anneal. The epitaxial source/drain regions 108 may have an impurity concentration in the range of 10¹⁹ cm⁻³ to 10²¹ cm⁻³. The n-type and/or p-type impurities for source/drain regions may be any of the impurities previously described. In some embodiments, the epitaxial source/drain regions 108 may be in situ doped during growth.

The epitaxial source/drain regions 108 may include one or more semiconductor material layers. For example, the epitaxial source/drain regions 108 may each include a liner layer 108A, a main layer 108B, and a finishing layer 108C (or more generally, a first semiconductor material layer, a second semiconductor material layer, and a third semiconductor material layer). Any number of semiconductor material layers may be used for the epitaxial source/drain regions 108. Each of the liner layer 108A, the main layer 108B, and the finishing layer 108C may be formed of different semiconductor materials and may be doped to different impurity concentrations. In some embodiments, the liner layer 108A may have a lesser concentration of impurities than the main layer 108B, and the finishing layer 108C may have a greater concentration of impurities than the liner layer 108A and a lesser concentration of impurities than the main layer 108B. In embodiments in which the epitaxial source/drain regions include three semiconductor material layers, the liner layers 108A may be grown in the source/drain recesses 104, the main layers 108B may be grown on the liner layers 108A, and the finishing layers 108C may be grown on the main layers 108B.

As a result of the epitaxy processes used to form the epitaxial source/drain regions 108, upper surfaces of the epitaxial source/drain regions have facets which expand laterally outward beyond sidewalls of the semiconductor fins 62 and the nanostructures 64, 66. However, the insulating fins 82 and the STI regions 72 block the lateral epitaxial growth. As described above in FIG. 6A, the dielectric layer 71 is converted to a high-quality carbon-rich oxide layer that is highly resistant to etching processes that use hydrofluoric acid (HF). Because of this, during the recessing of the dielectric layer 70 and the dielectric layer 71 to form the STI regions 72, a reduced amount of the dielectric layer 71 is removed (also referred to as oxide loss), which allows the remaining STI regions 72 to adequately protect sidewalls of the semiconductor fins 62. Therefore, when the epitaxial source/drain regions 108 are formed in adjacent semiconductor fins 62 as illustrated in FIG. 18C, they are adequately isolated from each other and prevented from merging with each other by the STI regions 72 and the insulating fins 82. As a result, device performance can be improved. For example, each STI region 72 is disposed between first sidewalls of adjacent semiconductor fins 62, wherein the STI region 72 extends along each of the first sidewalls, and wherein each first sidewall is below a corresponding epitaxial source/drain regions 108, the STI region 72 having the thickness T4 in the range from 20 nm to 160 nm. The epitaxial source/drain regions 108 contact the sidewalls of the insulating fins 82. In the illustrated embodiment, the epitaxial source/drain regions 108 are grown so that the upper surfaces of the epitaxial source/drain regions 108 are disposed below the top surfaces of the insulating fins 82. In various embodiments, the upper surfaces of the epitaxial source/drain regions 108 are disposed above the top surfaces of the insulating fins 82; the upper surfaces of the epitaxial source/drain regions 108 have portions disposed above and below the top surfaces of the insulating fins 82; or the like.

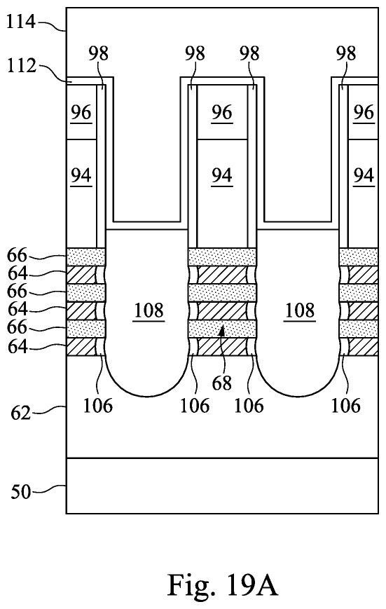

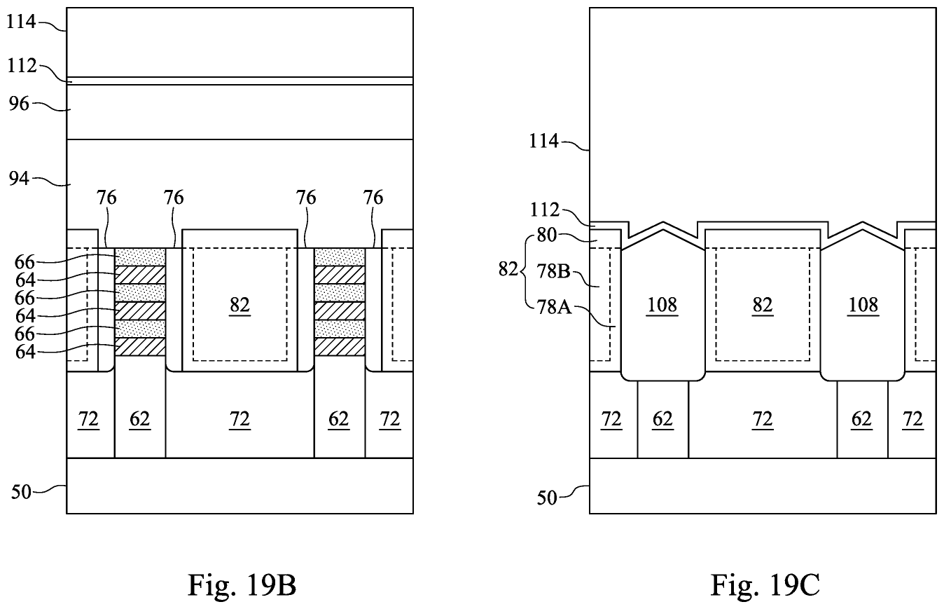

In FIGS. 19A-C, a first inter-layer dielectric (ILD) 114 is deposited over the epitaxial source/drain regions 108, the gate spacers 98, the masks 96 (if present) or the dummy gates 94. The first ILD 114 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 112 is formed over the epitaxial source/drain regions 108, the gate spacers 98, and the masks 96 (if present) or the dummy gates 94, and the first ILD 114 is formed over the CESL 112. The CESL 112 may be formed of a dielectric material, such as silicon nitride, silicon oxide, silicon oxynitride, or the like, having a high etch selectivity from the etching of the first ILD 114. The CESL 112 may be formed by any suitable method, such as CVD, ALD, or the like.

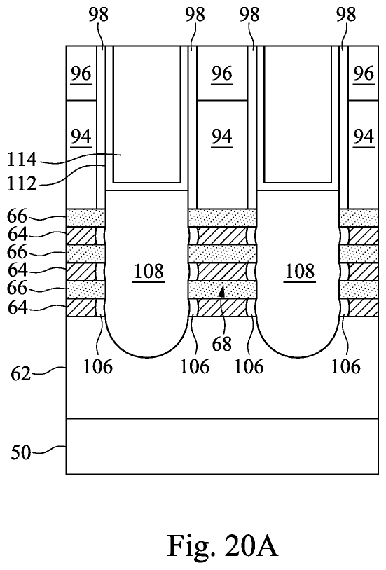

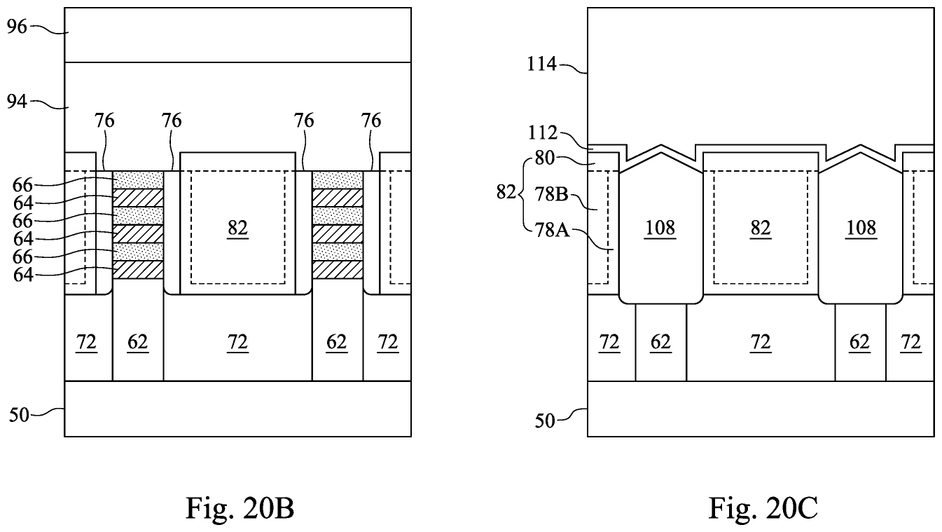

In FIGS. 20A-C, a removal process is performed to level the top surfaces of the first ILD 114 with the top surfaces of the masks 96 (if present) or the dummy gates 94. In some embodiments, a planarization process such as a chemical mechanical polish (CMP), an etch-back process, combinations thereof, or the like may be utilized. The planarization process may also remove the masks 96 on the dummy gates 94, and portions of the gate spacers 98 along sidewalls of the masks 96. After the planarization process, the top surfaces of the gate spacers 98, the first ILD 114, the CESL 112, and the masks 96 (if present) or the dummy gates 94 are coplanar (within process variations). Accordingly, the top surfaces of the masks 96 (if present) or the dummy gates 94 are exposed through the first ILD 114. In the illustrated embodiment, the masks 96 remain, and the planarization process levels the top surfaces of the first ILD 114 with the top surfaces of the masks 96.

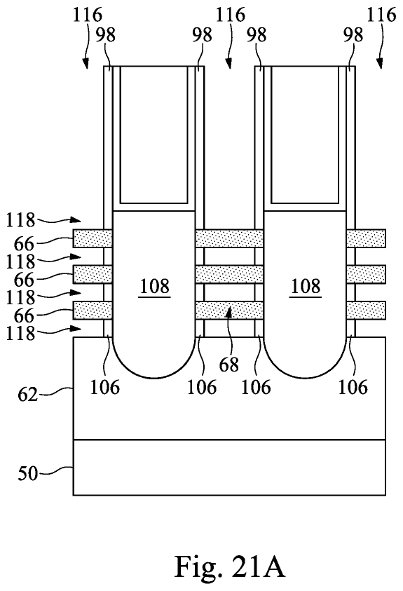

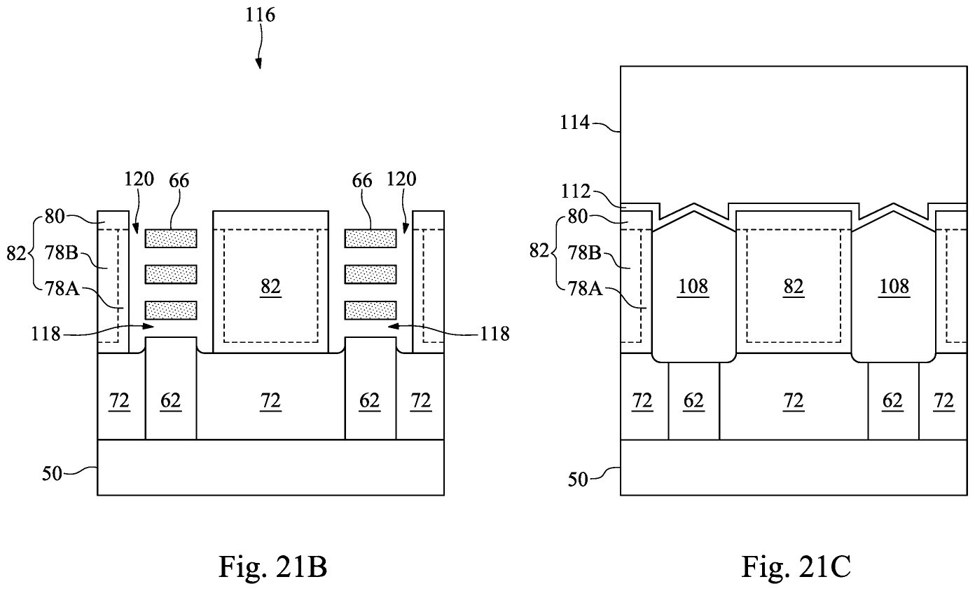

In FIGS. 21A-C, the masks 96 (if present) and the dummy gates 94 are removed in an etching process, so that recesses 116 are formed, thereby exposing channel regions 68. Portions of the nanostructures 66, which act as the channel regions 68, are disposed between adjacent pairs of the epitaxial source/drain regions 108. In some embodiments, the dummy gates 94 are removed by an anisotropic dry etch process. For example, the etching process may include a dry etch process using reaction gas(es) that selectively etch the dummy gates 94 at a faster rate than the first ILD 114 or the gate spacers 98.

The remaining portions of the sacrificial spacers 76 are then removed to expand the recesses 116, such that openings 120 are formed in regions between semiconductor fins 62 and the insulating fins 82, and the remaining portions of the nanostructures 64 are also removed to expand the recesses 116, such that openings 118 are formed in regions between the nanostructures 66. The remaining portions of the nanostructures 64 and the sacrificial spacers 76 can be removed by any acceptable etching process that selectively etches the material(s) of the nanostructures 64 and the sacrificial spacers 76 at a faster rate than the material of the nanostructures 66. The etching may be isotropic. For example, when the nanostructures 64 and the sacrificial spacers 76 are formed of silicon germanium and the nanostructures 66 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the nanostructures 66.

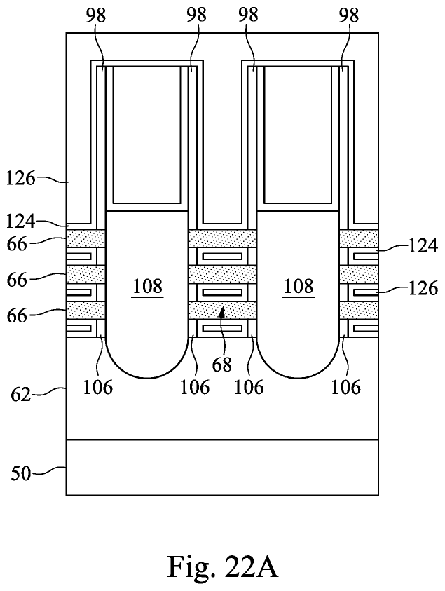

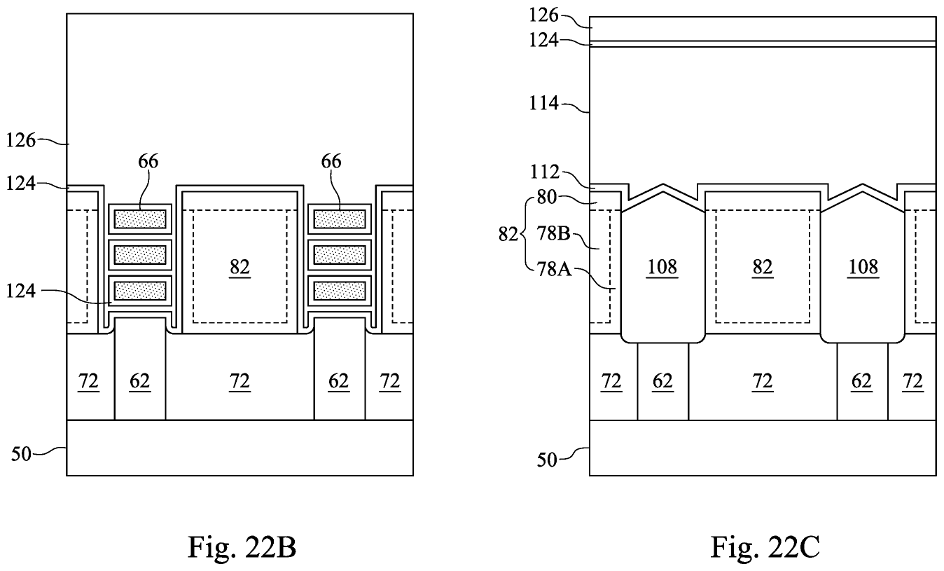

In FIGS. 22A-C, a gate dielectric layer 124 is formed in the recesses 116, and a gate electrode layer 126 is formed on the gate dielectric layer 124. The gate dielectric layer 124 and the gate electrode layer 126 are layers for replacement gates, and each may wrap around all (e.g., four) sides of the nanostructures 66. Thus, the gate dielectric layer 124 and the gate electrode layer 126 are formed in the openings 118 and the openings 120 (see FIGS. 21A-C).

The gate dielectric layer 124 is disposed on the sidewalls and/or the top surfaces of the semiconductor fins 62; on the top surfaces, the sidewalls, and the bottom surfaces of the nanostructures 66; on the sidewalls of the inner spacers 106 adjacent the epitaxial source/drain regions 108; on sidewalls of the gate spacers 98; and on the top surfaces and the sidewalls of the insulating fins 82. The gate dielectric layer 124 may also be formed on the top surfaces of the first ILD 114 and the gate spacers 98. The gate dielectric layer 124 may include an oxide such as silicon oxide or a metal oxide, a silicate such as a metal silicate, combinations thereof, multi-layers thereof, or the like. The gate dielectric layer 124 may include a high-k dielectric material (e.g., a dielectric material having a k-value greater than about 7.0), such as a metal oxide or a silicate of hafnium, aluminum, zirconium, lanthanum, manganese, barium, titanium, lead, and combinations thereof. Although a single-layered gate dielectric layer 124 is illustrated in FIGS. 22A-C, the gate dielectric layer 124 may include any number of interfacial layers and any number of main layers.

The gate electrode layer 126 may include a metal-containing material such as titanium nitride, titanium oxide, tungsten, cobalt, ruthenium, aluminum, combinations thereof, multi-layers thereof, or the like. Although a single-layered gate electrode layer 126 is illustrated in FIGS. 22A-C, the gate electrode layer 126 may include any number of work function tuning layers, any number of barrier layers, any number of glue layers, and a fill material.

The formation of the gate dielectric layers 124 in the n-type region 50N and the p-type region 50P may occur simultaneously such that the gate dielectric layers 124 in each region are formed of the same materials, and the formation of the gate electrode layers 126 may occur simultaneously such that the gate electrode layers 126 in each region are formed of the same materials. In some embodiments, the gate dielectric layers 124 in each region may be formed by distinct processes, such that the gate dielectric layers 124 may be different materials and/or have a different number of layers, and/or the gate electrode layers 126 in each region may be formed by distinct processes, such that the gate electrode layers 126 may be different materials and/or have a different number of layers. Various masking steps may be used to mask and expose appropriate regions when using distinct processes.

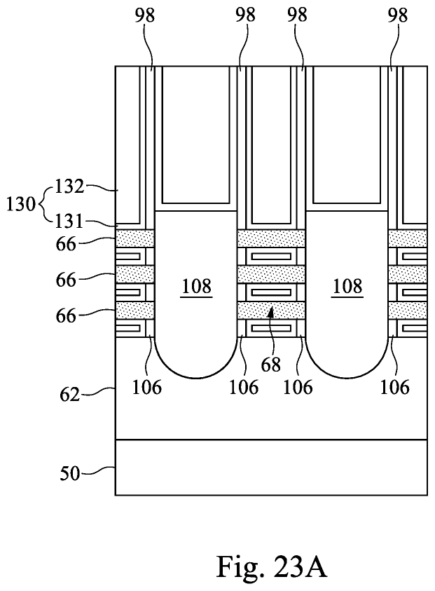

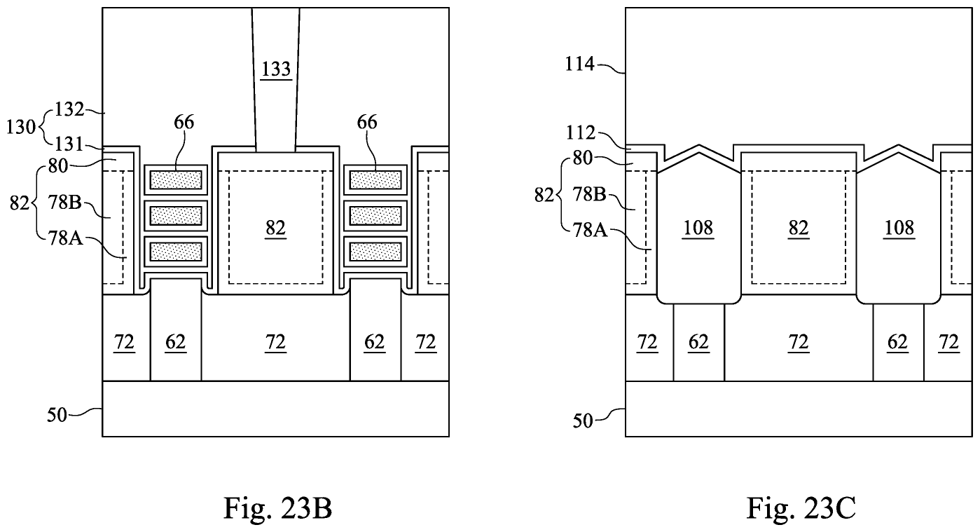

In FIGS. 23A-C, a removal process is performed to remove the excess portions of the materials of the gate dielectric layer 124 and the gate electrode layer 126, which excess portions are over the top surfaces of the first ILD 114 and the gate spacers 98, thereby forming gate structures 130. In some embodiments, a planarization process such as a chemical mechanical polish (CMP), an etch-back process, combinations thereof, or the like may be utilized. The gate dielectric layer 124, when planarized, has portions left in the recesses 116 (thus forming gate dielectrics 131 for the gate structures 130). The gate electrode layer 126, when planarized, has portions left in the recesses 116 (thus forming gate electrodes 132 for the gate structures 130). The top surfaces of the gate spacers 98; the CESL 112; the first ILD 114; and the gate structures 130 are coplanar (within process variations). The gate structures 130 are replacement gates of the resulting nano-FETs, and may be referred to as “metal gates.” The gate structures 130 each extend along top surfaces, sidewalls, and bottom surfaces of a channel region 68 of the nanostructures 66. The gate structures 130 fill the area previously occupied by the nanostructures 64, the sacrificial spacers 76, and the dummy gates 94.

In some embodiments, isolation regions 133 are formed extending through some of the gate structures 130. An isolation region 133 is formed to divide (e.g., cut) a gate structure 130 into multiple gate structures 130. The isolation region 132 may be formed of a dielectric material, such as silicon nitride, silicon oxide, silicon oxynitride, or the like, which may be formed by a deposition process such as CVD, ALD, or the like. As an example, to form the isolation regions 133, openings can be patterned in the desired gate structures 130 using any acceptable etch process, such as a dry etch, a wet etch, the like, or a combination thereof. The etching may be anisotropic. One or more layers of dielectric material may be deposited in the openings. A removal process may be performed to remove the excess portions of the dielectric material over the top surfaces of the gate structures 130, thereby forming the isolation regions 133.

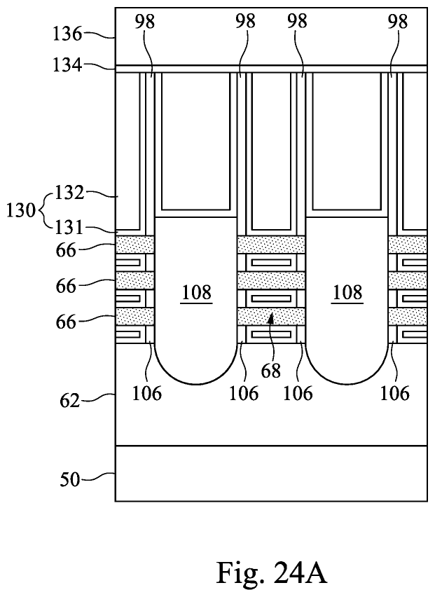

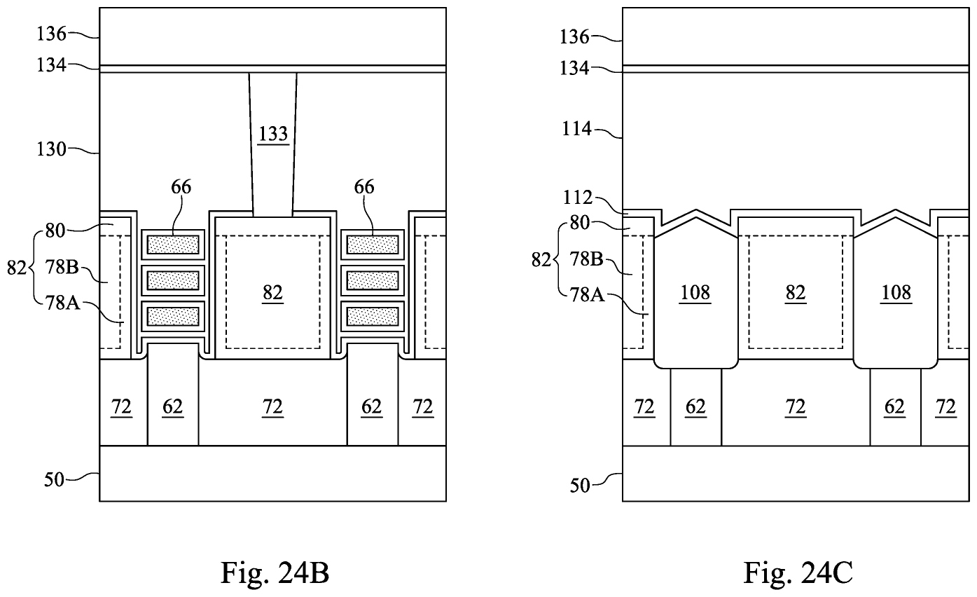

In FIGS. 24A-C, a second ILD 136 is deposited over the gate spacers 98, the CESL 112, the first ILD 114, and the gate structures 130. In some embodiments, the second ILD 136 is a flowable film formed by a flowable CVD method. In some embodiments, the second ILD 136 is formed of a dielectric material such as PSG, BSG, BPSG, USG, or the like, which may be deposited by any suitable method, such as CVD, PECVD, or the like.

In some embodiments, an etch stop layer (ESL) 134 is formed between the second ILD 136 and the gate spacers 98 98, the CESL 112, the first ILD 114, and the gate structures 130. The ESL 134 may include a dielectric material, such as silicon nitride, silicon oxide, silicon oxynitride, or the like, having a high etch selectivity from the etching of the second ILD 136.

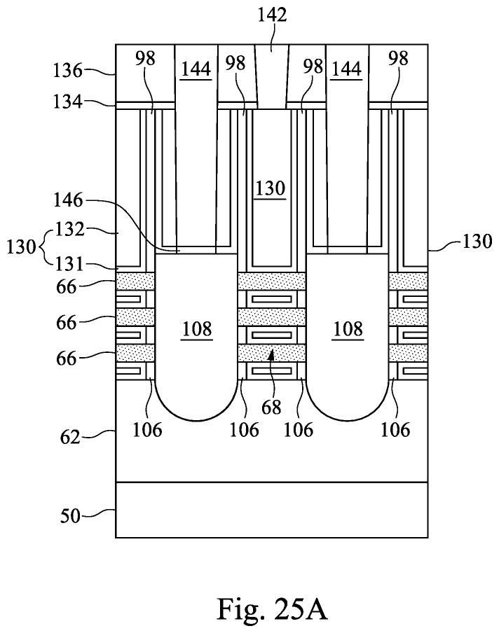

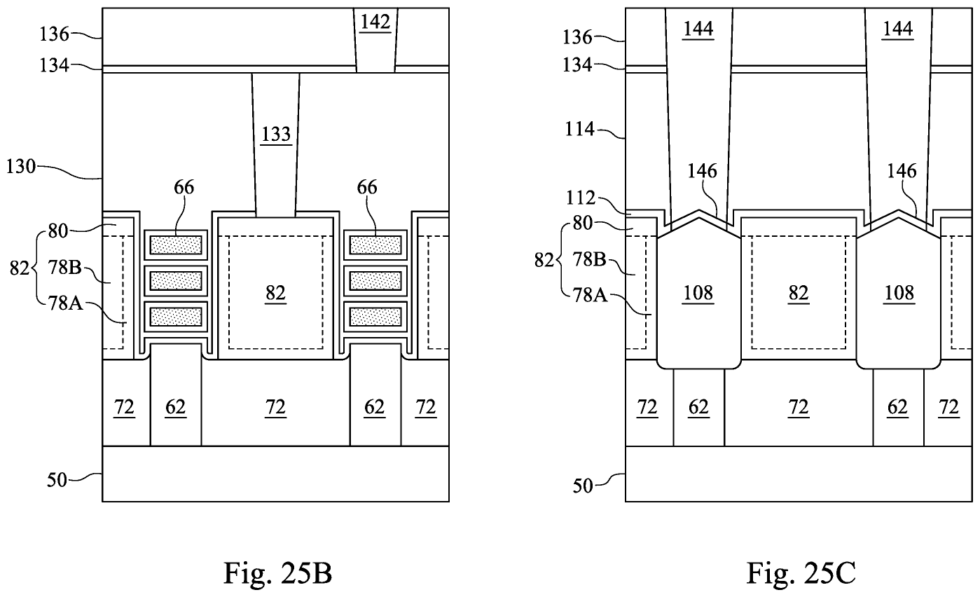

In FIGS. 25A-C, gate contacts 142 and source/drain contacts 144 are formed to contact, respectively, the gate structures 130 and the epitaxial source/drain regions 108. The gate contacts 142 are physically and electrically coupled to the gate structures 130. The source/drain contacts 144 are physically and electrically coupled to the epitaxial source/drain regions 108.

As an example to form the gate contacts 142 and the source/drain contacts 144, openings for the gate contacts 142 are formed through the second ILD 136 and the ESL 134, and openings for the source/drain contacts 144 are formed through the second ILD 136, the ESL 134, the first ILD 114, and the CESL 112. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 136. The remaining liner and conductive material form the gate contacts 142 and the source/drain contacts 144 in the openings. The gate contacts 142 and the source/drain contacts 144 may be formed in distinct processes, or may be formed in the same process. Although shown as being formed in the same cross-sections, it should be appreciated that each of the gate contacts 142 and the source/drain contacts 144 may be formed in different cross-sections, which may avoid shorting of the contacts.

Optionally, metal-semiconductor alloy regions 146 are formed at the interfaces between the epitaxial source/drain regions 108 and the source/drain contacts 144. The metal-semiconductor alloy regions 146 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 146 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the epitaxial source/drain regions 108 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 146. The material(s) of the source/drain contacts 144 can then be formed on the metal-semiconductor alloy regions 146.

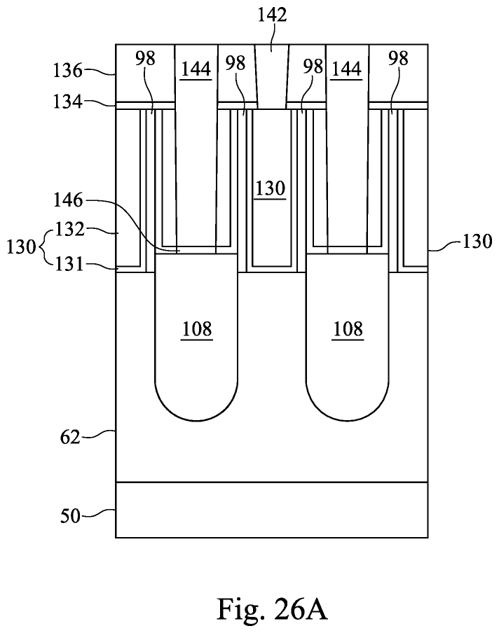

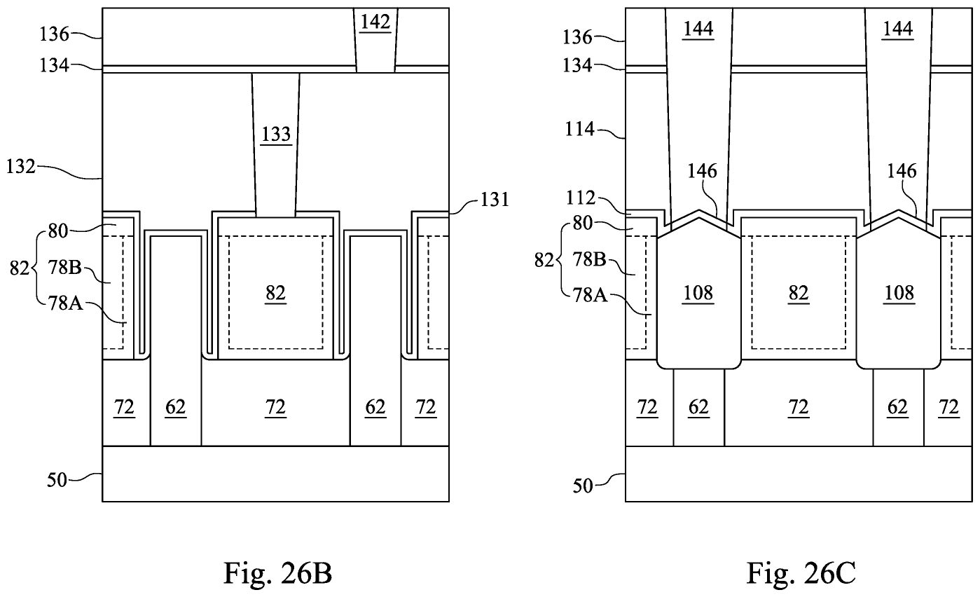

FIGS. 26A-26C illustrate an alternative embodiment. Unless specified otherwise, like reference numerals in this embodiment represent like components in the embodiment shown in FIGS. 1A through 25C formed by like processes. For example, the STI regions 72 are illustrated that are disposed on either side of each semiconductor fin 62. Accordingly, the process steps and applicable materials may not be repeated herein. The embodiment illustrated in FIGS. 26A-26C is different from the embodiment illustrated in FIGS. 1-25C in that the embodiment of FIGS. 26A-26C describes a fin field effect transistor (FinFET) device, rather than a nanostructure field effect transistor (NSFET). The step of forming the multi-layer stack 52 (described previously in FIG. 2) over the substrate 50 is omitted, and hence the multi-layer stack 52 including the alternating first semiconductor layers 54 and second semiconductor layers 56 is not formed over the substrate 50.

FIGS. 26A-26C show the semiconductor fins 62 that are formed in the substrate 50 by etching trenches in the substrate 50. The etching may be one or more of any acceptable etch process, such as a reactive ion etch (RIE), neutral beam etch (NBE), the like, or a combination thereof. The etching may be anisotropic. Although the semiconductor fins 62 are illustrated as having linear edges, the semiconductor fins 62 may have rounded edges or any other suitable shape. Because the multi-layer stack 52 is not formed prior to etching the trenches in the substrate 50 to form the semiconductor fins 62, the nanostructures 64 and the nanostructures 66 are not formed over the semiconductor fins 62, and top regions of the semiconductor fins 62 serve as channel regions for respective FinFET devices. In an embodiment, the height of each semiconductor fin 62 may be larger than 200 nm. In an embodiment, a ratio between the height H1 of each semiconductor fin 62 and the thickness T4 of the STI regions 72 may be in a range from 15 to 1.2.

STI regions 72 are formed over the substrate 50 and between adjacent semiconductor fins 62, such as in the trenches 60, in a manner similar to what was described in FIGS. 4 through 7. The STI regions 72 are disposed around at least a first portion of the semiconductor fins 62 such that at least a second portion of the semiconductor fins 62 protrude from between adjacent STI regions 72. The formation of the STI regions 72 includes the deposition of the dielectric layer 70 over top surfaces of the mask 58, and top surfaces and sidewalls of the semiconductor fins 62. The dielectric layer 71 is then formed in the trenches 60, over the dielectric layer 70 and over the masks 58.

After the formation of the dielectric layer 71, the anneal process 73 is then performed to cure or treat the dielectric layer 71, wherein the dielectric layer 71 is converted, such as by an oxidation process. During the anneal process 73, carbon from the dielectric layer 70 is released or diffuses into the dielectric layer 71, such that after the anneal process 73, the dielectric layer 71 comprises carbon-rich silicon oxide. After the anneal process 73, an atomic percentage concentration of carbon of the dielectric layer 71 is in a range from 0.5 percent to 4 percent. The dielectric layer 70 and the dielectric layer 71 are then recessed to form the STI regions 72 in a manner similar as to what was described previously in FIG. 7. The dielectric layer 70 and the dielectric layer 71 are recessed such that at least a portion of the semiconductor fins 62 protrude from between adjacent portions of the dielectric layer 70. Further, the top surfaces of the STI regions 72 may have a flat surface as illustrated, a convex surface, a concave surface (such as dishing), or a combination thereof by applying an appropriate etch. The dielectric layer 70 and the dielectric layer 71 may be recessed using any acceptable etching process, such as one that is selective to the materials of the dielectric layer 70 and the dielectric layer 71 (e.g., selectively etches the materials of the dielectric layer 70 and the dielectric layer 71 at a faster rate than the materials of the semiconductor fins 62). For example, an oxide removal may be performed using dilute hydrofluoric (dHF) acid as an etchant.

The STI regions 72 comprise a high-quality carbon-rich oxide that is highly resistant to etching processes (e.g., etching processes that were used to form the STI regions 72 as described previously in FIG. 7). As a result, during the formation of the STI regions 72, a reduced amount of the carbon-rich oxide (also referred to as oxide loss) is removed, which allows the remaining STI regions 72 to adequately protect sidewalls of the semiconductor fins 62. The epitaxial source/drain regions 108 formed in adjacent semiconductor fins 62 are adequately isolated from each other and prevented from merging with each other by the STI region 72. As a result, device performance can be improved. In addition, the STI regions 72 have an atomic percentage concentration of carbon that is in a range from 0.5 percent to 4 percent, which indicates that an anneal process that is performed to form the carbon-rich dielectric layer (e.g., an oxide) of the STI regions 72 can be performed at lower temperatures and for longer durations. This allows for thermal budget control for advanced technology nodes that require low total thermal budgets during device fabrication. In addition, due to the lower temperatures and the longer duration of the anneal process, a complete and efficient conversion to the carbon-rich oxide is possible, resulting in a more uniform oxide quality and composition (e.g., at a bottom of a trench with a high aspect ratio) after the conversion process.

After the formation of the STI regions 72, the sacrificial spacers 76 are formed over the STI regions 72, on sidewalls of the mask 58, and on sidewalls of the semiconductor fins 62. The formation of the sacrificial spacers 76 may be formed using similar processes and materials as those described previously in FIGS. 9A-10C. Insulating fins 82 (also referred to as hybrid fins or dielectric fins) are then formed between the sacrificial spacers 76 adjacent to the semiconductor fins 62 in a manner similar to that as described previously in FIGS. 11A-13C. The insulating fins 82 may insulate and physically separate subsequently formed epitaxial source/drain regions 108 from each other.

After the formation of the insulating fins 82, the mask 58 is removed using an etching process similar to that described previously in FIGS. 14A-14C. Next, dummy gate structures are formed in a manner similar to what was described previously in FIGS. 15A-16C. For example, the dummy gate layer 84 is formed on the insulating fins 82, the sacrificial spacers 76, and the semiconductor structures 62. A mask layer 86 may be deposited over the dummy gate layer 84. The mask layer 86 is then patterned using acceptable photolithography and etching techniques to form the masks 96. The pattern of the masks 96 is then transferred to the dummy gate layer 84 by any acceptable etching technique to form dummy gates 94. The dummy gates 94 covers the top surface of the semiconductor fins 62 that will be used to form channel regions. The pattern of the masks 96 may be used to physically separate adjacent dummy gates 94. The masks 96 can optionally be removed after patterning, such as by any acceptable etching technique. The gate spacers 98 are then formed over the semiconductor fins 62, and on exposed sidewalls of the masks 96 (if present) and the dummy gates 94.

After the formation of the dummy gates 94 and the gate spacers 98, source/drain recesses 104 are formed in the semiconductor fins 62 and the sacrificial spacers 76, using similar processes as those described previously in FIGS. 17A-17C. For example, the source/drain recesses may 104 extend through the sacrificial spacers 76 and into the semiconductor fins 62. The source/drain recesses 104 may also extend into the substrate 50.

The epitaxial source/drain regions 108 are then formed in recesses 104 in a manner similar and using similar materials as were described previously in FIGS. 18A-18C. Each dummy gate 94 (and corresponding channel region) is disposed between respective adjacent pairs of the epitaxial source/drain regions 108. In some embodiments, the gate spacers 98 are used to separate the epitaxial source/drain regions 108 from the dummy gates 94 by an appropriate lateral distance. A material of the epitaxial source/drain regions 108 may be selected to exert stress in the respective channel regions, thereby improving performance.

As a result of the epitaxy processes used to form the epitaxial source/drain regions 108, upper surfaces of the epitaxial source/drain regions 108 have facets which expand laterally outward beyond sidewalls of the semiconductor fins 62. However, the insulating fins 82 and the STI regions 72 block the lateral epitaxial growth. As described previously in FIG. 6A, the dielectric layer 71 is converted to a high-quality carbon-rich oxide layer that is highly resistant to etching processes that use hydrofluoric acid (HF). Because of this, during the recessing of the dielectric layer 70 and the dielectric layer 71 to form the STI regions 72, a reduced amount of the dielectric layer 71 is removed (also referred to as oxide loss), which allows the remaining STI regions 72 to adequately protect sidewalls of the semiconductor fins 62. Therefore, when the epitaxial source/drain regions 108 are formed in adjacent semiconductor fins 62, they are adequately isolated from each other and prevented from merging with each other by the STI regions 72 and the insulating fins 82. As a result, device performance can be improved. The epitaxial source/drain regions 108 contact the sidewalls of the insulating fins 82. In the illustrated embodiment, the epitaxial source/drain regions 108 are grown so that the upper surfaces of the epitaxial source/drain regions 108 are disposed below the top surfaces of the insulating fins 82. In various embodiments, the upper surfaces of the epitaxial source/drain regions 108 are disposed above the top surfaces of the insulating fins 82; the upper surfaces of the epitaxial source/drain regions 108 have portions disposed above and below the top surfaces of the insulating fins 82; or the like.

After the formation of the epitaxial source/drain regions 108, the contact etch stop layer (CESL) 112 and the first inter-layer dielectric (ILD) 114 are deposited over the epitaxial source/drain regions 108, the gate spacers 98, the masks 96 (if present) or the dummy gates 94 in a similar manner as to what was described previously in FIGS. 19A-19C. A removal process is performed to level the top surfaces of the CESL 112 and the first ILD 114 with the top surfaces of the masks 96 (if present) or the dummy gates 94, as described previously in FIGS. 20A-20C.

The masks 96 (if present) and the dummy gates 94 are then removed in an etching process similar to that described previously in FIGS. 21A-21C, so that recesses 116 are formed, thereby exposing the channel regions of the semiconductor fins 62. In some embodiments, the dummy gates 94 are removed by an anisotropic dry etch process. For example, the etching process may include a dry etch process using reaction gas(es) that selectively etch the dummy gates 94 at a faster rate than the first ILD 114 or the gate spacers 98.

In addition, remaining portions of the sacrificial spacers 76 are removed to expand the recesses 116 in a manner similar as was described previously in FIGS. 21A-21C, such that openings 120 are formed in regions between semiconductor fins 62 and the insulating fins 82. However, since the nanostructures 64 and the nanostructures 66 are not present, the openings 118 (shown previously in FIGS. 21A-21C) are not formed. The remaining portions of the sacrificial spacers 76 can be removed by any acceptable etching process that selectively etches the material(s) of the sacrificial spacers 76 at a faster rate than the material of the semiconductor fins 62. The etching may be isotropic. For example, when the sacrificial spacers 76 are formed of silicon germanium and the semiconductor fins 62 are formed of silicon, the etching process may be a wet etch using tetramethylammonium hydroxide (TMAH), ammonium hydroxide (NH₄OH), or the like.

After the removal of the dummy gates 94 and the remaining portions of the sacrificial spacers 76, the gate dielectric layer 124 is formed in the recesses 116, and the gate electrode layer 126 is formed on the gate dielectric layer 124, in a manner similar as was described previously in FIGS. 22A-22C. The gate dielectric layer 124 and the gate electrode layer 126 are layers for replacement gates, and each may be formed in the recesses 116 and the openings 120. Since there are no openings 118 present, the gate dielectric layer 124 and the gate dielectric layer 126 do not wrap around all (e.g., four) sides of any portion of the semiconductor fin 62. The gate dielectric layer 124 is disposed on the sidewalls and the top surfaces of the semiconductor fins 62; on sidewalls of the gate spacers 98; and on the top surfaces and the sidewalls of the insulating fins 82.

After the formation of the gate dielectric layer 124 and the gate electrode layer 126, a removal process is performed to remove the excess portions of the materials of the gate dielectric layer 124 and the gate electrode layer 126, which excess portions are over the top surfaces of the first ILD 114 and the gate spacers 98, thereby forming gate structures 130. The removal process (e.g., a planarization process) is similar to that described previously in FIGS. 23A-23C. The gate dielectric layer 124, when planarized, has portions left in the recesses 116 (thus forming gate dielectrics 131 for the gate structures 130). The gate electrode layer 126, when planarized, has portions left in the recesses 116 (thus forming gate electrodes 132 for the gate structures 130).

After the removal process is performed, the etch stop layer (ESL) 134 and the second ILD 136 are then deposited over the gate spacers 98, the CESL 112, the first ILD 114, and the gate structures 130 in a similar manner as was described previously in FIGS. 24A-24C. After the formation of the ESL 134 and the second ILD 136, the gate contacts 142 and the source/drain contacts 144 are formed to contact, respectively, the gate structures 130 and the epitaxial source/drain regions 108. The gate contacts 142 are physically and electrically coupled to the gate structures 130. The source/drain contacts 144 are physically and electrically coupled to the epitaxial source/drain regions 108. The gate contacts 142 and the source/drain contacts 144 may be formed in a similar manner and using similar materials as were described previously in FIGS. 25A-25C.

The embodiments of the present disclosure have some advantageous features. The embodiments include a method for forming a carbon-rich shallow trench isolation (STI) region, discussed in the context of forming a nanostructure field effect transistor (NSFET), a fin field effect transistor (FinFET) device, or the like. The methods include conformally depositing a first carbon-rich dielectric layer over and in a trench between two adjacent semiconductor fins. A second dielectric layer is then formed over the first dielectric layer to fill the trench between the adjacent fins. An anneal process is performed to convert the second dielectric layer to a third carbon-rich dielectric layer (e.g., an oxide). After the anneal process, an atomic percentage concentration of carbon of the third dielectric layer is in a range from 0.5 percent to 4 percent. As a result, a STI region can be formed that comprises the high-quality carbon-rich third dielectric layer that is highly resistant to subsequently performed etching processes (e.g., etching processes that use hydrofluoric acid (HF)). In addition, because the atomic percentage concentration of carbon of the third dielectric layer is in a range from 0.5 percent to 4 percent, lower anneal temperatures can be utilized during the anneal process to convert the second dielectric layer to the third dielectric layer, which allows for thermal budget control for advanced technology nodes that require low total thermal budgets during device fabrication. Further, as a result of being able to utilize lower anneal temperatures for longer durations, the complete and efficient conversion of the second dielectric layer to the third dielectric layer is possible, resulting in the third dielectric layer having a more uniform oxide quality and composition (e.g., at a bottom of the trench) after the conversion process even when the trench has a high aspect ratio.

In accordance with an embodiment, a method includes etching a first trench in a semiconductor substrate to form a first fin and a second fin; and forming a shallow trench isolation (STI) region in the first trench, where forming the STI region includes depositing a first dielectric layer over top surfaces of the first fin and the second fin, and on sidewalls and a bottom surface of the first trench, the first dielectric layer including carbon; depositing a second dielectric layer over the first dielectric layer, and in the first trench, where the second dielectric layer fills the first trench; and performing an anneal process, where the anneal process releases carbon from the first dielectric layer into the second dielectric layer. In an embodiment, depositing the first dielectric layer includes conformally depositing the first dielectric layer over the top surfaces of the first fin and the second fin, and on the sidewalls and the bottom surface of the first trench, and where the first dielectric layer includes SiOCN. In an embodiment, the method further includes depositing a third dielectric layer over top surfaces and sidewalls of the first dielectric layer, and in the first trench, where the third dielectric layer includes SiOCN, and where a carbon content of the first dielectric layer is different from a carbon content of the third dielectric layer. In an embodiment, after performing the anneal process, an atomic percentage concentration of carbon of the second dielectric layer is in a range from 0.5 percent to 4 percent. In an embodiment, after performing the anneal process, an atomic percentage concentration of carbon in the second dielectric layer is the largest at a point at a bottommost surface of the second dielectric layer, and an atomic percentage concentration of carbon in the second dielectric layer is the smallest at a point at a topmost surface of the second dielectric layer. In an embodiment, the first dielectric layer includes SiOₓC_{y}N_{z}, and where a value of y varies in a vertical direction from a bottom surface of the first dielectric layer to a top surface of the first dielectric layer. In an embodiment, the anneal process includes performing a first anneal process while exposing the second dielectric layer to a first oxygen-containing ambient; and performing a second anneal process while exposing the second dielectric layer to a second oxygen-containing ambient, where the first oxygen-containing ambient is different from the second oxygen-containing ambient.

In accordance with an embodiment, a method includes etching a semiconductor substrate to form a plurality of first fins that protrude from the semiconductor substrate, a first trench being interposed between adjacent first fins of the plurality of first fins; forming a shallow trench isolation (STI) region in the first trench, where forming the STI region includes conformally depositing a first dielectric layer over the plurality of first fins and on sidewalls and a bottom surface of the first trench, where the first dielectric layer includes carbon; forming a second dielectric layer over the first dielectric layer and in the first trench, where the second dielectric layer fills the first trench; and oxidizing the second dielectric layer, where during oxidizing the second dielectric layer, carbon from the first dielectric layer diffuses into the second dielectric layer. In an embodiment, oxidizing the second dielectric layer includes performing an anneal process while exposing the second dielectric layer to an oxygen-containing ambient. In an embodiment, after oxidizing the second dielectric layer, the first dielectric layer is completely consumed. In an embodiment, after oxidizing the second dielectric layer, the first dielectric layer is partially consumed. In an embodiment, conformally depositing the first dielectric layer includes depositing a third dielectric layer over the plurality of first fins and on the sidewalls and the bottom surface of the first trench; and depositing a fourth dielectric layer on top surfaces and sidewalls of the third dielectric layer, where a carbon content of the third dielectric layer and a carbon content of the fourth dielectric layer are different. In an embodiment, the third dielectric layer and the fourth dielectric layer include SiOCN. In an embodiment, after oxidizing the second dielectric layer, an atomic percentage concentration of carbon of the second dielectric layer is in a range from 0.5 percent to 4 percent. In an embodiment, the method further includes forming an epitaxial source/drain region in each of the plurality of first fins, wherein the STI region extends along sidewalls of each of the plurality of first fins, and wherein a ratio between a height of each fin of the plurality of first fins and a thickness of the STI region is in a range from 15 to 1.2.

In accordance with an embodiment, a semiconductor device includes a first plurality of fins extending from a substrate; a shallow trench isolation (STI) layer between adjacent fins of the first plurality of fins, where an atomic percentage concentration of carbon of the STI layer is in a range from 0.5 percent to 4 percent; a gate structure over the adjacent fins of the first plurality of fins and the STI layer; and a source/drain region in each of the adjacent fins of the first plurality of fins, each source/drain region being adjacent to the gate structure. In an embodiment, the STI layer further includes a first dielectric liner; and a first dielectric layer over the first dielectric liner, where the first dielectric liner is disposed between the first plurality of fins and the first dielectric layer, and between a top surface of the substrate and the first dielectric layer, where the first dielectric liner includes SiOCN. In an embodiment, the STI layer further includes a second dielectric liner disposed between the first dielectric liner and the first dielectric layer, where the second dielectric liner includes SiOCN, and where a carbon concentration of the first dielectric liner and a carbon concentration of the second dielectric liner are different. In an embodiment, an atomic percentage concentration of carbon at a first point in the STI layer is larger than an atomic percentage concentration of carbon at a second point in the STI layer, where the first point is vertically below and overlapped by the second point. In an embodiment, a ratio between a height of each fin of the first plurality of fins and a thickness of the STI layer is in a range from 15 to 1.2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
etching a first trench in a semiconductor substrate to form a first fin and a second fin; and
forming a shallow trench isolation (STI) region in the first trench, wherein forming the STI region comprises:
depositing a first dielectric layer over top surfaces of the first fin and the second fin, and on sidewalls and a bottom surface of the first trench, the first dielectric layer comprising carbon;
depositing a second dielectric layer over the first dielectric layer, and in the first trench, wherein the second dielectric layer fills the first trench; and
performing an anneal process, wherein the anneal process releases carbon from the first dielectric layer into the second dielectric layer.

2. The method of claim 1, wherein depositing the first dielectric layer comprises conformally depositing the first dielectric layer over the top surfaces of the first fin and the second fin, and on the sidewalls and the bottom surface of the first trench, and wherein the first dielectric layer comprises SiOCN.

3. The method of claim 1, further comprising:
depositing a third dielectric layer over top surfaces and sidewalls of the first dielectric layer, and in the first trench, wherein the third dielectric layer comprises SiOCN, and wherein a carbon content of the first dielectric layer is different from a carbon content of the third dielectric layer.

4. The method of claim 3, wherein after performing the anneal process, an atomic percentage concentration of carbon of the second dielectric layer is in a range from 0.5 percent to 4 percent.

5. The method of claim 4, wherein after performing the anneal process, an atomic percentage concentration of carbon in the second dielectric layer is the largest at a point at a bottommost surface of the second dielectric layer, and an atomic percentage concentration of carbon in the second dielectric layer is the smallest at a point at a topmost surface of the second dielectric layer.

6. The method of claim 1, wherein the first dielectric layer comprises SiOₓC_{y}N_{z}, and wherein a value of y varies in a vertical direction from a bottom surface of the first dielectric layer to a top surface of the first dielectric layer.

7. The method of claim 1, wherein the anneal process comprises:
performing a first anneal process while exposing the second dielectric layer to a first oxygen-containing ambient; and
performing a second anneal process while exposing the second dielectric layer to a second oxygen-containing ambient, wherein the first oxygen-containing ambient is different from the second oxygen-containing ambient.

8. A method comprising:
etching a semiconductor substrate to form a plurality of first fins that protrude from the semiconductor substrate, a first trench being interposed between adjacent first fins of the plurality of first fins;
forming a shallow trench isolation (STI) region in the first trench, wherein forming the STI region comprises:
conformally depositing a first dielectric layer over the plurality of first fins and on sidewalls and a bottom surface of the first trench, wherein the first dielectric layer comprises carbon;
forming a second dielectric layer over the first dielectric layer and in the first trench, wherein the second dielectric layer fills the first trench; and
oxidizing the second dielectric layer, wherein during oxidizing the second dielectric layer, carbon from the first dielectric layer diffuses into the second dielectric layer.

9. The method of claim 8, wherein oxidizing the second dielectric layer comprises performing an anneal process while exposing the second dielectric layer to an oxygen-containing ambient.

10. The method of claim 9, wherein after oxidizing the second dielectric layer, the first dielectric layer is completely consumed.

11. The method of claim 9, wherein after oxidizing the second dielectric layer, the first dielectric layer is partially consumed.

12. The method of claim 8, wherein conformally depositing the first dielectric layer comprises:
depositing a third dielectric layer over the plurality of first fins and on the sidewalls and the bottom surface of the first trench; and
depositing a fourth dielectric layer on top surfaces and sidewalls of the third dielectric layer, wherein a carbon content of the third dielectric layer and a carbon content of the fourth dielectric layer are different.

13. The method of claim 12, wherein the third dielectric layer and the fourth dielectric layer comprise SiOCN.

14. The method of claim 8, wherein after oxidizing the second dielectric layer, an atomic percentage concentration of carbon of the second dielectric layer is in a range from 0.5 percent to 4 percent.

15. The method of claim 8, further comprising:
forming an epitaxial source/drain region in each of the plurality of first fins, wherein the STI region extends along sidewalls of each of the plurality of first fins, and wherein a ratio between a height of each fin of the plurality of first fins and a thickness of the STI region is in a range from 15 to 1.2.

16. A semiconductor device comprising:
a first plurality of fins extending from a substrate;
a shallow trench isolation (STI) layer between adjacent fins of the first plurality of fins, wherein an atomic percentage concentration of carbon of the STI layer is in a range from 0.5 percent to 4 percent;
a gate structure over the adjacent fins of the first plurality of fins and the STI layer; and
a source/drain region in each of the adjacent fins of the first plurality of fins, each source/drain region being adjacent to the gate structure.

17. The semiconductor device of claim 16, wherein the STI layer further comprises:
a first dielectric liner; and
a first dielectric layer over the first dielectric liner, wherein the first dielectric liner is disposed between the first plurality of fins and the first dielectric layer, and between a top surface of the substrate and the first dielectric layer, wherein the first dielectric liner comprises SiOCN.

18. The semiconductor device of claim 17, wherein the STI layer further comprises:
a second dielectric liner disposed between the first dielectric liner and the first dielectric layer, wherein the second dielectric liner comprises SiOCN, and wherein a carbon concentration of the first dielectric liner and a carbon concentration of the second dielectric liner are different.

19. The semiconductor device of claim 16 wherein an atomic percentage concentration of carbon at a first point in the STI layer is larger than an atomic percentage concentration of carbon at a second point in the STI layer, wherein the first point is vertically below and overlapped by the second point.

20. The semiconductor device of claim 16, wherein a ratio between a height of each fin of the first plurality of fins and a thickness of the STI layer is in a range from 15 to 1.2.
